(19) United States
(12) Patent Application Publication
(10) Pub. No.: US 2026/0313786 A1
(43) Pub. Date: Oct. 8, 2026

(54) SYSTEMS WITH VERTICAL POWER DISTRIBUTION NETWORK VIAS AND MULTIPLE PRINTED CIRCUIT BOARD SUBASSEMBLIES

(71) Applicant: PCB Automation Inc., Campbell, CA (US)

(72) Inventors: Zhiping Yang, Campbell, CA (US); Sek Kwan Eddie Mok, Irvine, CA (US)

(21) Appl. No.: 19/710,775

(22) Filed: Jun. 17, 2026

Related U.S. Application Data
(63) Continuation-in-part of application No. 19/066,088, filed on Feb. 27, 2025.
(60) Provisional application No. 63/560,626, filed on Mar. 1, 2024.

(51) Int. Cl. H05K 1/02; H05K 1/11; H05K 1/14; H05K 1/181

(52) U.S. Cl. CPC H05K 1/0263; H05K 1/115; H05K 1/144; H05K 1/181; H05K 1/141; H05K 2201/041; H05K 2201/10545

(57) ABSTRACT

A system that includes a first and a PCB subassembly, an IC (that is coupled, at least electrically, to at least one of the first or second PCB subassembly), a power module (that is coupled, at least electrically, to at least one of the first or second PCB subassembly), and a SV-PDN via. The SV-PDN via is included in at least one of the first or second PCB subassembly. The SV-PDN via includes a first and second power distribution path, the first and second power distribution path are at least electrically coupled to a same pad. The first and second power distribution path are routed with closer via-to-via spacing compared to a first and second signal path according to a set of via-to-via spacing rules.

### CROSS REFERENCE TO OTHER APPLICATIONS

This application is a continuation in part of U.S. Patent Application No 19/066,088 entitled METHODS AND SYSTEMS FOR CONFIGURING CONDUCTIVE PATHS IN A PRINTED CIRCUIT BOARD ASSEMBLY (PCBA) FOR ENHANCED POWER DISTRIBUTION filed February 27, 2025, which claims priority to U.S. Provisional Patent Application No. 63/560,626 entitled SYSTEM AND METHOD FOR DESIGNING AND MANUFACTURING A PRINTED CIRCUIT BOARD WITH AN ENHANCED VERTICAL POWER DISTRIBUTION NETWORK filed March 01, 2024, each of which is incorporated herein by reference for all purposes.

### BACKGROUND OF THE INVENTION

Improved systems and/or techniques for routing conductive paths within a printed circuit board (PCB) are described in U.S. Patent Application No 19/066,088 entitled METHODS AND SYSTEMS FOR CONFIGURING CONDUCTIVE PATHS IN A PRINTED CIRCUIT BOARD ASSEMBLY (PCBA) FOR ENHANCED POWER DISTRIBUTION and filed on February 27, 2025. Further improvements to the systems and/or techniques described therein would be desirable.

### BRIEF DESCRIPTION OF THE DRAWINGS

Various embodiments of the invention are disclosed in the following detailed description and the accompanying drawings.

FIG. 1 is a diagram illustrating a schematic embodiment of a printed circuit board assembly (PCBA) configured using a conventional power distribution network (PDN) following standard printed circuit board (PCB) guideline approaches.

FIG. 2A is a diagram illustrating a schematic embodiment of the PCBA depicting the current distribution in the PCB configured using the conventional power distribution network (PDN) following the standard PCB design guideline approaches.

FIG. 2B is a diagram illustrating a schematic embodiment of the PCBA depicting the current distribution in the PCB configured using a vertical power distribution network (PDN) following the standard PCB design guideline approaches.

FIG. 3A is a diagram illustrating a schematic embodiment of a printed circuit board assembly (PCBA) using the conventional power distribution network (PDN) following PCB design guideline approaches, in accordance with an embodiment of the present disclosure.

FIG. 3B is a diagram illustrating a schematic embodiment of the printed circuit board assembly (PCBA) using the vertical power distribution network (PDN) following the PCB design guideline approaches, in accordance with an embodiment of the present disclosure.

FIG. 3C is a diagram illustrating a perspective view schematic embodiment of the printed circuit board assembly (PCBA) of FIGS. 3A and 3B.

FIG. 3D illustrates a top view schematic embodiment of a drill hole size (DHS) of at least one conductive path of the printed circuit board assembly (PCBA) of FIG. 3A and 3B;

FIG. 3E illustrates a schematic embodiment of the printed circuit board assembly (PCBA) of FIG. 3B depicting current distribution in a bare PCB, in accordance with an embodiment of the present disclosure.

FIG. 4A illustrates a schematic embodiment of a set of first terminals and a set of second terminals of the bare printed circuit board (PCB) arranged in a square pattern, in accordance with an embodiment of the present disclosure.

FIG. 4B illustrates a schematic embodiment of the set of first terminals and the set of second terminals of the bare printed circuit board (PCB) arranged in a hexagon pattern, in accordance with an embodiment of the present disclosure.

FIG. 4C illustrates a schematic embodiment of the set of first terminals and the set of second terminals of the bare printed circuit board (PCB) arranged in a diamond pattern, in accordance with an embodiment of the present disclosure.

FIGS. 5A and 5B collectively illustrate a flowchart embodiment depicting a method for applying a set of spacing rules to determine a number of conductive paths in the printed circuit board assembly (PCBA), in accordance with an embodiment of the present disclosure.

FIG. 6A illustrates an example representation of the printed circuit board assembly (PCBA) depicting a plurality of component pads electrically connected to each first terminal and each second terminal through via-in-pad configuration, in accordance with an embodiment of the present disclosure.

FIG. 6B illustrates an example representation of the printed circuit board assembly (PCBA) depicting the plurality of component pads electrically connected to each first terminal and each second terminal through dog-bone fan-out configuration, in accordance with an embodiment of the present disclosure.

FIG. 7 illustrates a flow diagram embodiment of a method for configuring conductive paths in the printed circuit board assembly (PCBA).

FIG. 8 is a flowchart illustrating an embodiment of a process to assemble a system with SV-PDN vias and multiple PCB subassemblies.

FIG. 9 is a diagram illustrating an embodiment of a system with a power PCB subassembly and a signal PCB subassembly which are connected through board-to-board bonding.

FIG. 10 is a diagram illustrating an embodiment of a system with a power module semi-embedded in a power PCB subassembly.

FIG. 11 is a diagram illustrating an embodiment of a system with a power module semi-embedded in a power PCB subassembly.

FIG. 12 is a diagram illustrating an embodiment of a system with three PCB subassemblies, where a power module is fully embedded in a top PCB subassembly associated with high-speed signal transmission.

FIG. 13 is a diagram illustrating an embodiment of a system with three PCB subassemblies, where a power module is fully embedded in a middle PCB subassembly associated with power transmission.

FIG. 14 is a diagram illustrating an embodiment of a system with three PCB subassemblies, where a power module is fully embedded in a bottom PCB subassembly associated with power transmission.

FIG. 15 is a diagram illustrating an embodiment of a system with three PCB subassemblies, where a first power module is fully embedded in a top PCB subassembly associated with high-speed signal transmission and a second power module is fully embedded in a bottom PCB subassembly associated with power transmission.

FIG. 16 is a diagram illustrating an embodiment of a system with three PCB subassemblies, where a first power module is fully embedded in a top PCB subassembly associated with high-speed signal transmission and a second power module is surface mounted to a bottom PCB subassembly associated with power transmission.

FIG. 17 is a diagram illustrating an embodiment of a sequence of steps to manufacture a PCB subassembly with an embedded power module using multiple laminations.

FIG. 18 is a diagram illustrating an embodiment of a sequence of steps to manufacture a PCB subassembly with an embedded power module using a single lamination.

FIG. 19A is a diagram illustrating an embodiment of steps 1 – 3 of a first process to connect multiple PCB subassemblies using sintering paste.

FIG. 19B is a diagram illustrating an embodiment of steps 4 and 5 to connect multiple PCB subassemblies using sintering paste and extra HDI layers.

FIG. 20 is a diagram illustrating an embodiment of a second process for connecting multiple PCB subassemblies.

FIG. 21 is a diagram illustrating an embodiment of a third process for connecting multiple PCB subassemblies.

### DETAILED DESCRIPTION

The invention can be implemented in numerous ways, including as a process; an apparatus; a system; a composition of matter; a computer program product embodied on a computer readable storage medium; and/or a processor, such as a processor configured to execute instructions stored on and/or provided by a memory coupled to the processor. In this specification, these implementations, or any other form that the invention may take, may be referred to as techniques. In general, the order of the steps of disclosed processes may be altered within the scope of the invention. Unless stated otherwise, a component such as a processor or a memory described as being configured to perform a task may be implemented as a general component that is temporarily configured to perform the task at a given time or a specific component that is manufactured to perform the task. As used herein, the term ‘processor’ refers to one or more devices, circuits, and/or processing cores configured to process data, such as computer program instructions.

A detailed description of one or more embodiments of the invention is provided below along with accompanying figures that illustrate the principles of the invention. The invention is described in connection with such embodiments, but the invention is not limited to any embodiment. The scope of the invention is limited only by the claims and the invention encompasses numerous alternatives, modifications and equivalents. Numerous specific details are set forth in the following description in order to provide a thorough understanding of the invention. These details are provided for the purpose of example and the invention may be practiced according to the claims without some or all of these specific details. For the purpose of clarity, technical material that is known in the technical fields related to the invention has not been described in detail so that the invention is not unnecessarily obscured.

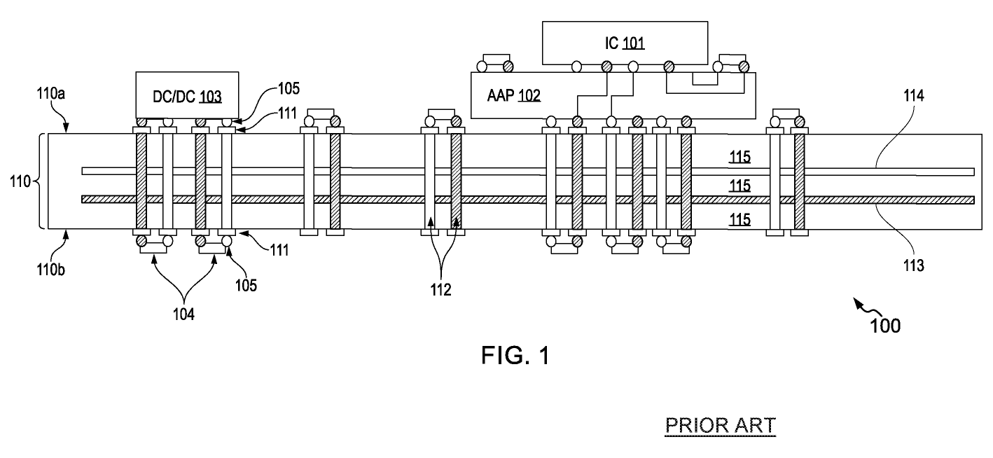

Before describing various embodiments of super vertical power distribution network (SV-PDN) vias in combination with multiple printed circuit board (PCB) subassemblies, it may be helpful to first describe SV-PDN vias. FIGS. 1-7 describe some embodiments of SV-PDN vias.

### Super Vertical Power Distribution Network SV-PDN Vias

Generally, an assembled printed circuit board (PCBA) 100 in FIG. 1 includes a bare printed circuit board (PCB) 110 and various discrete and active components assembled on the assembled PCBA 100 (hereinafter interchangeably referred to as ‘the PCBA 100’). The circuit board components may include complex integrated circuit (IC) devices 101 (e.g., processors, memories, Application Specific Integrated Circuits (ASICs)), Area Array Package (AAP) 102, DC/DC converters 103 (e.g., direct current (DC)-to-direct current (DC) converters, switching power suppliers, and/or Low Dropout (LDO) power suppliers), and discrete components 104 (e.g., resistors, capacitors, and the like).

In recent times, complex IC device technologies have evolved to produce higher performances. Further, the IC devices generated using the complex IC device technologies may include many advanced circuit components (such as GPU, CPU, TPU, memory, high-speed transceivers, etc.) with faster signal edges and higher clock rates. Thus, using a higher number of advanced circuit components on the bare PCB 110 (hereinafter interchangeably referred to as ‘the PCB 110’) offer increased functionality. However, the PCB 110 with many advanced IC components faces the increasing difficulty of routing high-speed signals and avoiding interference. Further, the PCB using the complex IC technologies tends to consume more power to perform various functions. Also, more circuit board components in the PCB generate additional heat, complicating thermal management and potentially reducing the lifespan of the PCB. The total power consumption of the PCB is an important factor for operation costs. One part of the power loss is from the power distribution networks (PDN) between the DC-DC converters and the IC dies. The power losses from the PDN networks can be quite large for high-current applications. As a result, PCB manufacturers may focus on reducing the current carrying density to reduce the power loss in the form of heat loss by increasing the copper area (i.e., dedicated power and ground layers, thicker copper planes with more copper, increasing power trace/plane, or plate thicker copper in the plated through hole (PTH), etc.) to the IC devices being manufactured using the complex IC technologies.

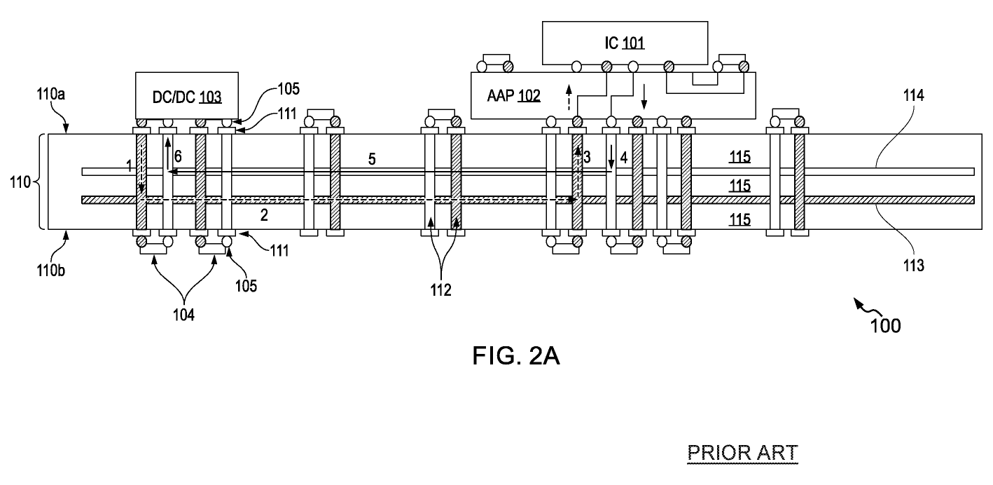

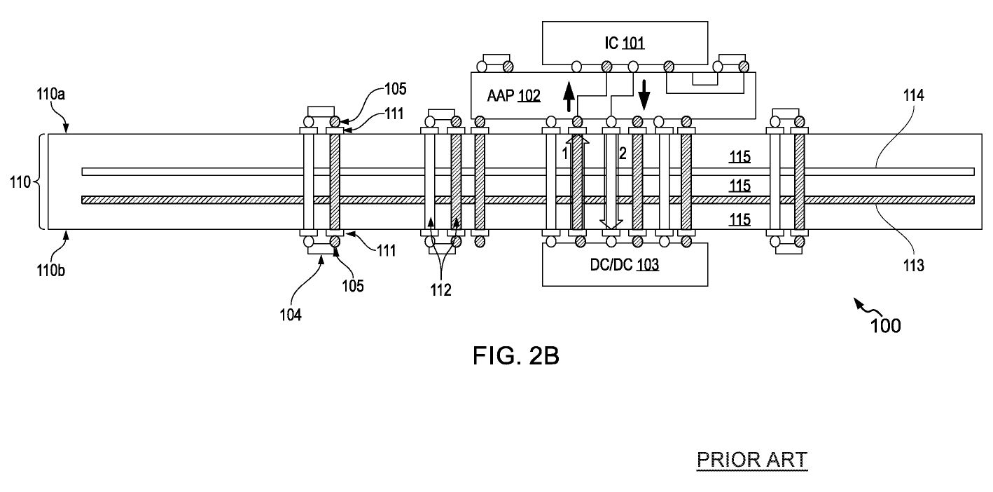

Referring to FIG. 2A, the assembled printed circuit board (PCBA) or the PCBA 100 configured using the conventional power delivery network (PDN) following standard PCB design approaches is shown. In general, the PCB 110 provides both electrical and mechanical connections for other components such as ICs, decoupling capacitors, resistors, inductors, connectors, etc. The decoupling capacitors, the resistors, and the inductors may be collectively referred to as ‘the discrete components 104’. In an embodiment, the PCB 110 may be a multi-layer PCB board. The multi-layer PCB may include horizontal ground plane(s) 114, power plane(s) 113, signal traces on copper layers, horizontal dielectric layers 115, and an array of vertically plated-through-hole (PTH) vias 112 interconnecting the internal multi-layers to the surface mount pads 111, etc. The surface mount pads 111 are then connected to the ICs, DC converters, or other components by solder balls or pins (see, 105). The solder balls 105 may include power pins, ground pins, signal pins, and the like. Hence, the term ‘solder balls 105’ is interchangeably referred to as ‘the ground pins 105’ or ‘the power pins 105’ as per the requirements for the power and ground pins. To simplify PCB design and manufacturing, PCB designers usually assign different copper layers as signal layers, power layers, and ground layers based on their functions.

The conventional PDN approaches to providing power supply signals (hereinafter interchangeably referred to as “the conventional power distribution approach”) involve installing the direct current (DC)/direct current (DC) converters 103 and the Area Array Package (AAP) devices 102 on a top side 110a of the PCB 110. The DC/DC converters 103 may be configured to convert a DC input voltage from one level (such as 48 Volt or 12 Volt) to another level (such as 1V or 0.9V). The DC/DC converters 103 may be a single chip, a module with multiple components, or a group of components. Further, the PCB 110 typically includes the array of vertically plated-through-hole (PTH) vias 112 (hereinafter interchangeably referred to as ‘the PTH vias 112’) which connect conductive features (e.g., data lines, the power planes 113, the ground planes 114, etc.) within the PCB 110 to the surface mount pads 111 electrically connected to the AAP devices 102 and/or the DC/DC converters 103. Furthermore, the PCB 110 includes a bottom side 110b which is opposite to the mounting locations of the AAP devices 102 (as shown in FIG. 2A). The PCB 110 may include the discrete components 104 such as decoupling capacitors (as shown in FIG. 2A). The decoupling capacitors (i.e., the discrete components 104) may be electrically connected to the bottom side 110b and/or the top side 110a of the PCB 110. This ensures minimizing loop inductance from the decoupling capacitors to the AAP devices 102. The PCB 110 may further include at least one integrated circuit (IC) 101 coupled to the AAP devices 102. In this configuration, the DC current flow path in the PCBA 100 is as follows:

the power pins 105 of the DC/DC converters 103 → flowing through the associated power pads 111 → flowing vertically through the PTH vias 112 associated with the power pins 105 of the DC/DC converters 103 →flowing horizontally through the power planes 113 → flowing vertically through the PTH vias 112 associated with the power pins 105 of the AAP devices 102 → flowing through the associated power pads 111 → the power pins 105 associated with the AAP devices 102 → flowing through the IC 101 → ground pins associated with the AAP devices 102 → flowing through the associated surface mount pads 111 → flowing Vertically through the PTH vias 112 associated with ground pins of the AAP devices 102 → flowing Horizontally through the ground planes 114 → flowing Vertically through the PTH vias 112 associated with ground pins of the DC/DC converters 103 → flowing through the associated surface mount pads 111 → the ground pins 105 of the DC/DC converters 103.

Thus, the current flows from the DC/DC contact pin (i.e., the power pins 105) both vertically through the surface mount pads 111 and PTH vias 112 and horizontally through the power planes 113 and the ground planes 114 within the PCB 110 (as shown in FIG. 2A). To reduce the power losses from horizontal current paths, designers traditionally use more Power/Ground layers (such as the power planes 113 and the ground planes 114) and/or increase the copper thickness of the power/ground planes. The power losses from the vertical current paths are usually difficult to control since the PTH vias 112 are determined by the power/ground pins of the AAP devices 102. However, increasing the number of power/ground pins associated with the AAP devices 102 incurs higher fabrication costs. In some cases, the designers may use a smaller package pin pitch or pattern to increase the number of power/ground pins associated with the AAP devices 102 which is undesirable and increases the complexity and cost of the PCBA 100. In standard PCB design guidelines, the ratio between the number of power/ground pins and the associated PTH vias 112 is one-to-one (i.e., one via assigned to one power/ground pin). To mitigate the challenges associated with the conventional PDN approaches with horizontal and vertical current paths, a recent approach to providing the high-current power supply signals to the IC 101 through the AAP devices 102 is implemented which will be explained with reference to FIG. 2B.

Referring to FIG. 2B, the recent approach (hereinafter interchangeably referred to as ‘the vertical power distribution approach’) to providing the high-current power supply signals to the IC device 101 involves installing the DC/DC converters 103 and the AAP devices 102 on the opposite sides of the PCB 110. For example, the AAP devices 102 are placed on the top side 110a of the PCB 110, and decoupling capacitors can be integrated into the DC/DC converters 103, the PCB 110, and/or the AAP 102. In this configuration, the DC current flows vertically in the PCB 110 is as follows:

the power pins 105 associated with the DC/DC converters 103 → flowing through the associated DC/DC converter surface mount pads 111 → flowing vertically through the PTH vias 112 associated with the power pins 105 shared between the DC/DC converters 103 and the AAP devices 102 → flowing through the associated AAP surface mount pads 111 → the power pins 105 associated with the AAP devices 102 → flowing through the IC 101 → the ground pins 105 associated with the AAP devices 102 → flowing through the associated AAP surface mount pads 111 → flowing vertically through the PTH vias 112 associated with the ground pins 105 shared between the DC/DC converters 103 and the AAP devices 102 → flowing through the associated DC/DC converters surface mount pads 111 → the ground pins associated with the DC/DC converters 103.

As shown in FIG. 2B, the configuration of the PCB 110 significantly reduces the horizontal current flow path over the power planes 113 and the ground planes 114. In both the configurations disclosed in FIGS. 2A and 2B, a standard PCB guideline for the number of power/ground surface mount pads 111 or power/ground pins 105 and the associated PTH vias 112 are 1:1, so the PTH vias 112 become the bottleneck for the vertical current flows. To decrease the vertical current density by increasing the number of the PTH vias 112 in high-current areas, designers conventionally may use different pin patterns without increasing the footprint area, increase the package size to increase the number of power and ground pins, request PCB fabricator to plate thicker copper in the via than nominal, and the like. As a result, the conditioning effects of the above-described approaches are limited or require a costly reconfiguration of the ground and power pins and AAP packages.

Further, the standard PCB guideline approaches disclosed in FIGS. 2A and 2B generally implement the same design and manufacturing 1 surface mount pad&pin-to-1 PTH rules for all signals (such as digital signals, analog signals, power signals, and ground signals) on the PCB 110. It is to be noted that the designers are focused on the digital and analog signals which usually require one PTH via per component pad and pin. However, for the digital and analog signals, if one PTH via fails for open or short failure, the entire functionality of the PCB 110 fails.

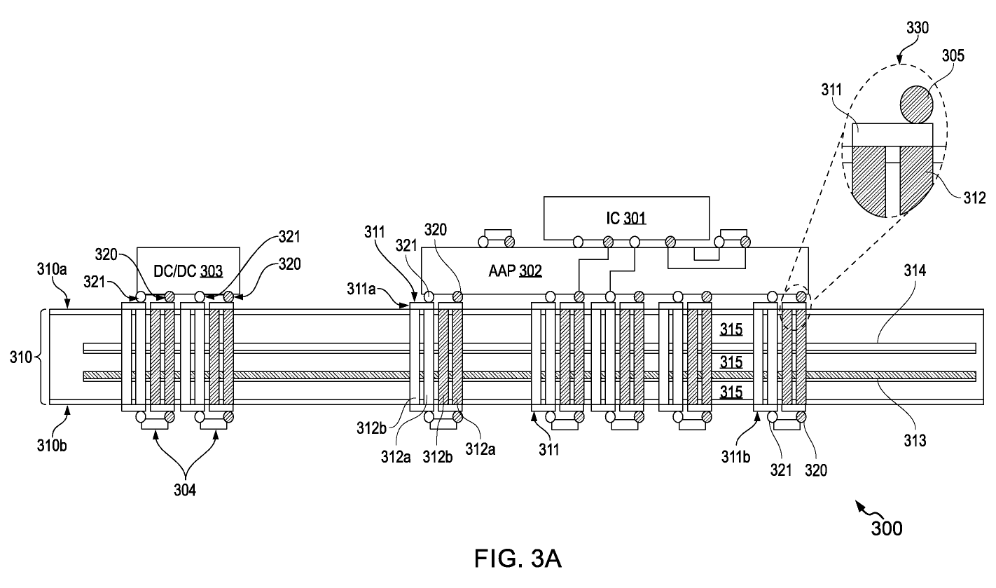

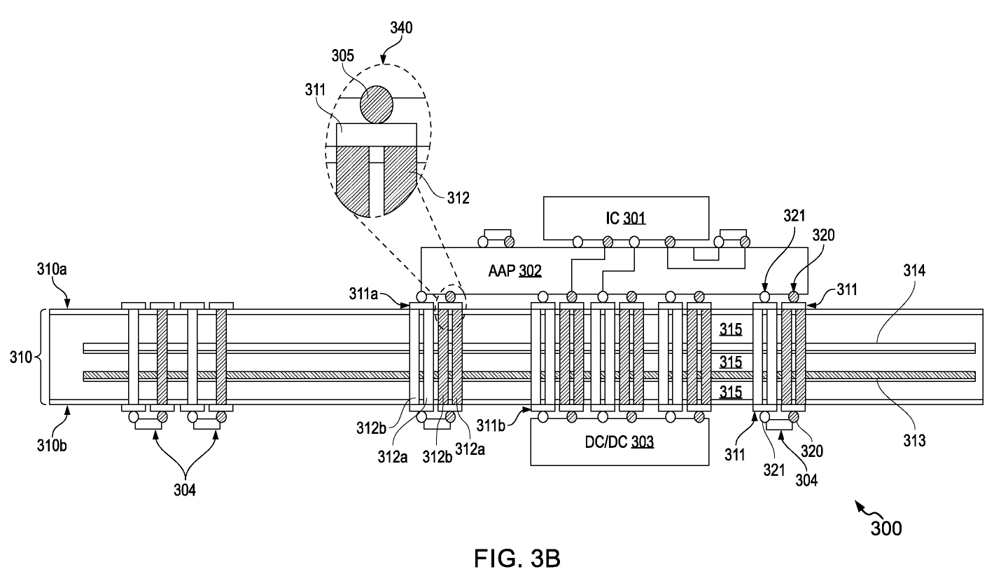

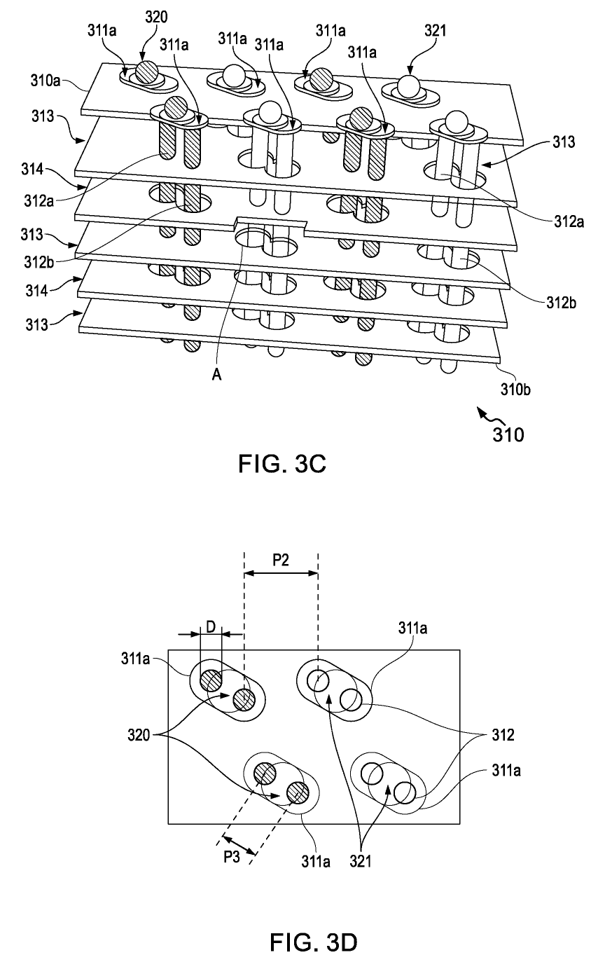

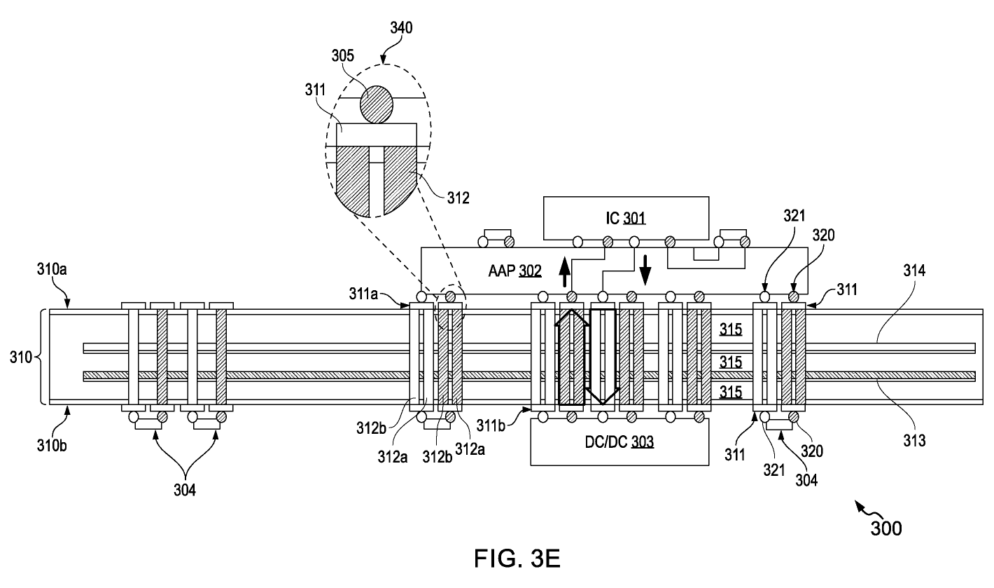

FIG. 3A illustrates a schematic representation of an assembled printed circuit board (PCBA) 300, in accordance with an embodiment of the present disclosure. The PCBA 300 includes a bare PCB 310. The PCB 310 includes a top surface 310a and a bottom surface 310b. The PCB 310 further includes a set of first terminals 320 and a set of second terminals 321. The set of first terminals 320 may be power pins in the PCBA 300 in the bare PCB 310 (hereinafter interchangeably referred to as ‘the PCB 310’). For illustration purposes, the set of first terminals 320 is represented using a circle provided with a hatching pattern, and the set of second terminals 321 is represented using a white circle. Some examples of the AAP devices 302 may include Ball Grid Array (BGA) devices and Ceramic Column Grid Array Package (CCGA) devices. The set of first terminals 320 is electrically connected to at least one power plane 313 in the PCB 310 for voltage supply (e.g., VDD, VCC). The set of second terminals 321 may be ground pins in the PCB 310. The set of second terminals 321 is electrically connected to at least one ground plane 314 of the PCB 310. The at least one power plane 313 and the at least one ground plane 314 are collectively referred to as copper layers configured in the PCB 310. Further, the PCB 310 is configured with dielectric layers 315 between the copper layers (or the power plane 313 and the ground plane 314). Additionally, or alternatively, the PCB 310 may include a set of third terminals (which is not shown in FIG. 3A). The set of third terminals may be signal pins used for data communication in the PCBA 300.

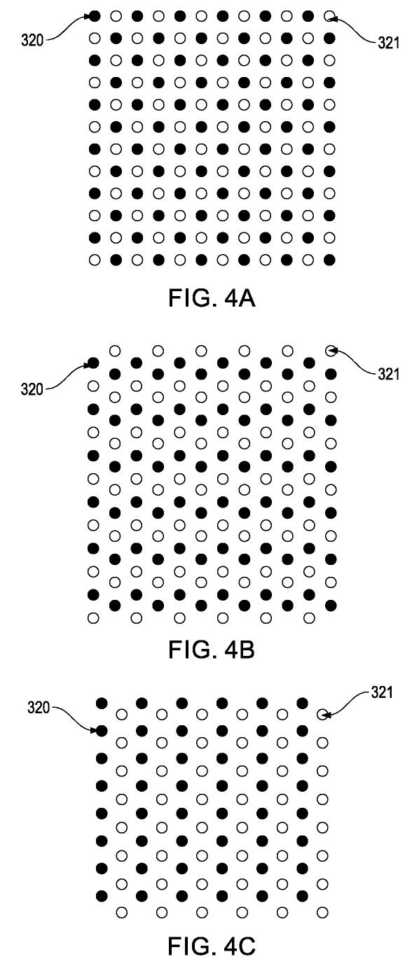

In an embodiment, the set of first terminals 320 and the set of second terminals 321 are configured on the PCB 310 in a square pattern (as shown in FIG. 4A). In other words, the set of first terminals 320 and the set of second terminals 321 are arranged in a checkerboard-like pattern within the PCB 310. In another embodiment, the set of first terminals 320 and the set of second terminals 321 are configured on the PCB 310 in a hexagon pattern (as shown in FIG. 4B). In this configuration, each first terminal of the set of first terminals 320 and each second terminal of the set of second terminals 321 are surrounded by six neighboring terminals, forming a hexagonal layout (or a honeycomb-like structure). In another embodiment, the set of first terminals 320 and the set of second terminals 321 are configured on the PCB 310 in a diamond pattern. In this configuration, the set of first terminals 320 and the set of second terminals 321 are arranged in a diagonal grid structure (as shown in FIG. 4C). In other words, the set of first terminals 320 and the set of second terminals 321 are aligned along diagonals rather than the typical rows and columns of a square or rectangular grid. For illustration purposes, the set of first terminals 320 is shown as white circles and the set of second terminals 321 is shown as black circles in FIGS. 4A, 4B and 4C. However, the set of first terminals 320 and the set of second terminals 321 may be represented using any other assignment patterns, therefore it should not be considered to limit the scope of the present disclosure.

Further, the PCB 310 includes a plurality of component pads 311. The plurality of top component pads 311 may be configured on the top surface 310a and the bottom surface 310b of the PCB 310. The plurality of component pads 311 is electrically connected to the set of first terminals 320 and the set of second terminals 321. The plurality of component pads 311 may be made of copper or any other conductive material as per design feasibility and requirements. The plurality of component pads 311 configured on the top surface 310a of the PCB 310 corresponds to a set of top component pads 311a. The plurality of component pads 311 configured on the bottom surface 310b of the PCB 310 corresponds to a set of bottom component pads 311b.

Further, the PCBA 300 may include a plurality of circuit board components, such as at least one integrated circuit (IC) 301, area array package (AAP) devices 302, power modules 303 (e.g., DC/DC converters), discrete components 304, and sockets and connectors (not shown in FIGS.). The plurality of circuit board components is electrically connected to the plurality of component pads 311 of the PCB 310. In particular, the plurality of circuit board components is electrically connected in the printed circuit board system (PCBA) 300 through at least the set of top component pads 311a and the set of bottom component pads 311b. The AAP devices 302 are generally soldered to the set of top component pads 311a. The power modules 303 may include, but not limited to, DC/DC converters, power field effect transistors (FET), capacitors, resistors, inductors, power controllers, etc. The DC/DC converters may be configured to convert a DC input voltage from one level (such as 48 Volt or 12 Volt) to another level (such as 1V or 0.9V). The DC/DC converters may be a single chip, a module with multiple components, or a group of components. The power modules 303 are electrically connected to the set of top component pads 311a (in FIG. 3A) and the set of bottom component pads 311b (in FIG. 3B). Further, decoupling capacitors may be electrically connected to the set of top component pads 311a and/or the set of bottom component pads 311b.

The PCB 310 includes at least one conductive path 312 for each first terminal of the set of first terminals 320 and each second terminal of the set of second terminals 321. The at least one conductive path 312 (also referred to as ‘the at least one vertical conductive path 312’) corresponds to plated-through-hole (PTH) vias. The plated through-hole (PTH) vias are a type of vias used in the PCB 310 to electrically and thermally connect different copper layers (such as the power plane 313 and the ground plane 314) of the PCB 310. The at least one conductive path 312 is configured by drilling a hole through the copper layers of the PCB 310 and then electroplating with a conductive material (e.g., copper) to establish a reliable electrical connection.

The at least one conductive path 312 is configured for each first terminal of the set of first terminals 320 and each second terminal of the set of second terminals 321 based at least on applying a set of spacing rules which will be explained further in detail. As shown, each component pad of the plurality of component pads 311 is electrically connected to a corresponding conductive path of the at least one conductive path 312 associated with each first terminal of the set of first terminals 320 and each second terminal of the set of second terminals 321. In this configuration, only two conductive paths are defined for each first terminal and each second terminal. In another configuration, three or more conductive paths may be defined for each first terminal and each second terminal.

As shown in FIGS. 3A and 3B. the at least one vertical conductive path 312 includes a primary conductive path 312a and at least one secondary conductive path 312b. The primary conductive path 312a is electrically coupled to a corresponding first terminal of the set of first terminals 320 and a corresponding second terminal of the set of second terminals 321. Further, the at least one secondary conductive path 312b is electrically coupled to the corresponding first terminal of the set of first terminals 320 and the corresponding second terminal of the set of second terminals 321 through a conductive feature.

In one implementation, each component pad of the plurality of component pads 311 is electrically connected to the corresponding vertical conductive path of the at least one conductive path 312 associated with each first terminal of the set of first terminals 320 and each second terminal of the set of second terminals 321 through a via-in-pad configuration (as shown in FIGS. 3A). In other words, the vertical conductive path (see, 312 of an enlarged portion 330 in FIG. 3A) of the at least one conductive path 312 is placed directly on a component pad (see 311 of the enlarged portion 330 in FIG. 3A) of the plurality of component pads 311. This enables the direct connection of the at least one conductive path 312 with a first terminal (see, 305 of the enlarged portion 330 in FIG. 3A) of the set of first terminals 320 associated with the at least one conductive path 312. Similarly, the at least one conductive path 312 is electrically connected to the set of second terminals 321 in the via-in pad configuration.

In another implementation, each component pad of the plurality of component pads 311 is electrically connected to the corresponding vertical conductive path of the at least one conductive path 312 associated with each first terminal of the set of first terminals 320 and each second terminal of the set of second terminals 321 through a dog-bone fan-out configuration (as shown in FIG. 3B). In other words, the at least one conductive path 312 is placed at a distance from the first terminal (see, 305 of an enlarged portion 340 in FIG. 3B). The at least one conductive path 312 is electrically connected to the corresponding component pad (see, 311 of the enlarged portion 340 in FIG. 3B) of the plurality of component pads 311. This enables the direct connection of the conductive path 312 with the first terminal 305 of the set of first terminals 320 associated with the at least one conductive path 312. Similarly, the at least one conductive path 312 is electrically connected to the set of second terminals 321 in the dog-bone fan-out configuration.

Referring to FIG. 3E in conjunction with FIG. 3B, to provide the high-current power supply signals to the IC device (i.e., the AAP devices 302) involves installing the DC/DC converters 303 on the opposite side of the AAP devices 302 in the PCBA 300 (as shown in FIG. 3B). In this configuration, the DC current flow in the PCB 310 is as follows:
the set of first terminals 320 associated with the DC/DC converters (i.e., the power modules 303) → flowing vertically through the set of first terminals 320 associated with the at least one conductive path 312 shared between the DC/DC converters (i.e., the power modules 303) and the AAP devices 302 → the set of first terminals 320 associated with the AAP devices 302 → flowing through the IC 301 → the set of second terminals 321 associated with the AAP devices 302 → flowing vertically through the set of second terminals 321 associated with the at least one conductive path 312 shared between the DC/DC converters (i.e., the power modules 303) and the AAP devices 302 → the set of second terminals 321 associated with the DC/DC converters (i.e., the power modules 303).

This configuration significantly reduces the horizontal current flow path over the at least one power plane 313 or the at least one ground plane 314. Further, the number of the set of first terminals 320/the set of second terminals 320 and the associated at least one conductive path 312 are 1:2, so the cross-sectional current carrying area of the at least one conductive path 312 is doubled and opens the bottleneck for the vertical current flows as compared to the approaches discussed with reference to FIGS. 1, 2A and 2B.

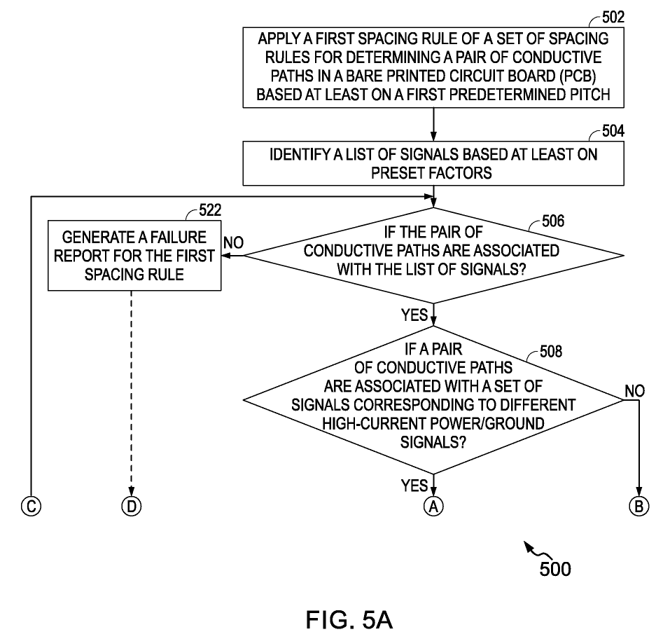

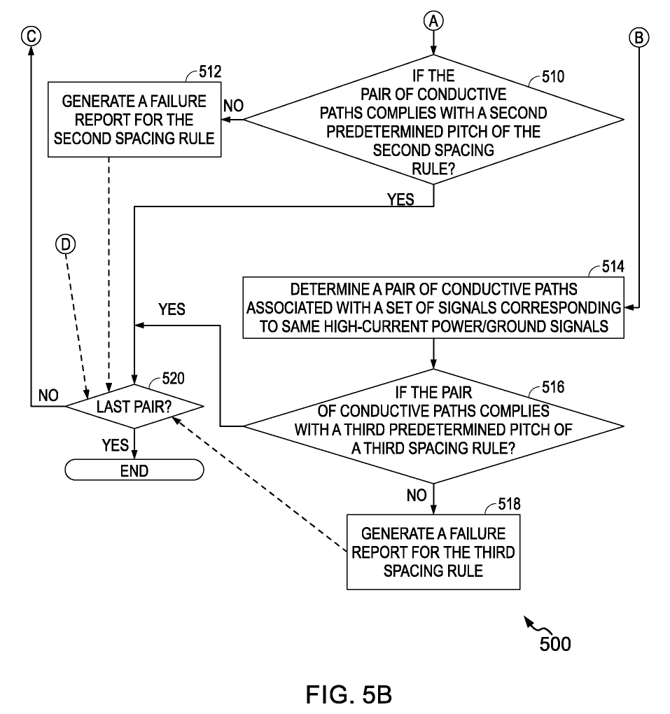

As explained above, the present disclosure provides a solution to accommodate more than one PTH via (or the conductive path) for at least each first terminal of the set of first terminals 320 and each second terminal of the set of second terminals 321. One of the important design and manufacturing parameters for PTH via (or the conductive path) is via- to-via spacing. The via-to-via spacing determines the number of the PTH vias (or the conductive paths) in a fixed area of the PCB 310. The via-to-via spacing corresponds to the set of spacing rules. The set of spacing rules may include three level spacing rules which will be explained with reference to FIGS. 5A and 5B.

FIGS. 5A and 5B collectively illustrate a flowchart depicting a method 500 for applying the set of spacing rules to determine the number of conductive paths in the PCB 300, in accordance with an embodiment of the present disclosure. The set of spacing rules is related to distance between two conductive paths which are all pairs of conductive paths in the PCB 310. The pair of conductive paths in the PCB 310 are associated with the set of first terminals 320 and the set of second terminals 321. In other words, the pair of conductive paths determined by applying the set of spacing rules corresponds to the at least one conductive path 312 associated with at least the set of first terminals 320 and the set of second terminals 321. The method 500 starts at step 502.

At 502, a first spacing rule of the set of spacing rules is applied for all conductive paths in the PCB 310. The first spacing rule is applied based on a first predetermined pitch between each pair of conductive paths in the PCB 310. The pair of conductive paths determined based on the first spacing rule corresponds to the at least one conductive path 312. It is to be noted that the first spacing rule is applied for all the conductive paths with a drill hole size (DHS) irrespective of signal properties. For illustration purposes, a DHS of a conductive path is represented as ‘D’ (as shown in FIG. 3D), where ‘D’ is a non-negative number.

At 504, a list of signals is identified based at least on preset factors. Herein, the preset factors correspond to factors defined for identifying the high-current power/ground signals. In an embodiment, the list of signals may be identified if the pair of conductive paths in the PCB 310 violate the first spacing rule. For example, the list of signals may be high-current power/ground signals. The definition of the high-current power/ground signals can be subjective and based on the application cases. In one example scenario, the top 3 highest current power signals and associated ground signals may be selected as the list of signals. In another example scenario, all power/ground signals with more than 100 amperes (A) may be selected as the list of signals. Thereafter, a second spacing rule of the set of spacing rules is applied for determining the pair of conductive paths complying with the second spacing rule. In one example, the pair of conductive paths may be associated with the set of first terminals 320. In another example, the pair of conductive paths may be associated with the set of second terminals 321. In another example, one conductive path of the pair of conductive paths may be associated with the set of first terminals 320 and another conductive path of the pair of conductive paths may be associated with the set of second terminals 321. One or more operations of the second spacing rule are explained concerning steps 506, 508, and 510.

Thereafter, determine if the pair of conductive paths are associated with the list of signals that are selected based on the preset factors (see, 506). In one scenario, upon determining the pair of conductive paths are associated with the list of signals (i.e., high-current power/ground signals), step 508 is performed. In another scenario, if the pair of conductive paths are not associated with the list of signals (i.e., the high-current power/ground signals), step 522 is performed. At 522, a failure report is generated for the first spacing rule to include the pair of conductive paths violating the first spacing rule (or the first predetermined pitch).

At 508, check if a pair of conductive paths are associated with a set of signals corresponding to different high-current power/ground signals. The set of signals of the different high-current power/ground signals may be determined from the list of signals. Herein, the term ‘the different high-current power/ground signals’ relates to the pair of conductive paths being associated with the different set of first terminals 320 or set of second terminals 321. For example, one high-current power signal may be associated with a first terminal A and another high-current power signal may be associated with a first terminal B. It is to be noted that a conductive path associated with the first terminal A and a conductive path associated with the first terminal B are different. Hence, the two conductive paths (or the pair of conductive paths) associated with the different power terminals (such as the first terminal A and the first terminal B) are considered as the pair of conductive paths associated with the set of signals corresponding to the different high-current power signals. Similarly, the pair of conductive paths associated with the different high-current ground signals are determined.

Further, determine whether the pair of conductive paths complies with a second predetermined pitch P2 (in FIG. 3D) defined for the second spacing rule (see, 510). The pair of conductive paths determined based on the second spacing rule corresponds to the at least one conductive path 312. It is to be noted that upon determining the pair of conductive paths are associated with the set of signals corresponding to the different high-current power/ground signals, step 510 is performed. If the pair of conductive paths are not associated with the set of signals corresponding to the different high-current power/ground signals, step 514 is performed.

In one scenario, if the pair of conductive paths complies with the second predetermined pitch, step 520 is performed. In another scenario, if the pair of conductive paths violates the second predetermined pitch P2 (in FIG. 3D), step 512 is performed. At 512, a failure report is generated for the second spacing rule to include the pair of conductive paths violating the second predetermined pitch.

At 514, determining a pair of conductive paths associated with a set of signals corresponding to same high-current power/ground signals is determined. The set of signals of the same high-current power/ground signals may be determined from the list of signals. Herein, the term ‘the same high-current power/ground signals’ relates to the pair of conductive paths being associated with the same set of first terminals 320 or set of second terminals 321. For example, one high-current power signal may be associated with a first terminal A, and another high-current power signal may be associated with a second terminal A. It is to be noted that the pair of conductive paths are associated with the first terminal A and the second terminal A. Hence, the two conductive paths (or the pair of conductive paths) associated with the same power terminals are considered as the pair of conductive paths associated with the set of signals corresponding to the same high-current power signals.

Based on determining the pair of conductive paths associated with the set of signals corresponding to the same high-current power/ground signals, determine whether the pair of conductive paths complies with a third predetermined pitch P3 (in FIG. 3D) defined for a third spacing rule (see, 516). The pair of conductive paths determined based on the third spacing rule corresponds to the at least one conductive path 312. In one scenario, if the pair of conductive paths complies with the third predetermined pitch, step 520 is performed. At 520, determine if the pair of conductive paths is the last pair of a total number of the pairs of conductive paths. If the pair of conductive paths is the last pair, the flowchart of the method 500 ends, else steps 506-522 are reiterated. Further, if the pair of conductive paths violates the third predetermined pitch P3 (in FIG. 3D), step 518 is performed. At 518, a failure report is generated for the third spacing rule to include the pair of conductive paths violating the third predetermined pitch.

In an embodiment, the first predetermined pitch, the second predetermined pitch, and the third predetermined pitch may be defined as a distance from the center of a conductive path of the pair of conductive paths to the center of another conductive path of the pair of conductive paths. In another embodiment, the first predetermined pitch, the second predetermined pitch, and the third predetermined pitch may be defined as minimal drill edge to drill edge. As explained above, each conductive path of the at least one conductive path 312 is a plated-through-hole (PTH) via. Generally, the at least one conductive path 312 is configured in the PCB 310 using conventional techniques such as drilling. Hence, each conductive path (such as the at least one conductive path 312) is configured with the drill hole size (DHS). The DHS indicates a diameter of each conductive path. For example, the DHS of each conductive path of the at least one conductive path 312 may be 10 mils.

In one scenario, for the conductive paths associated with regular signals which are not a part of the identified high-current power/ground signals (i.e., the first spacing rule), a pad size (diameter) is 20 mils and an air gap is 5 mils, so an anti-pad size is 30 mils. Herein the anti-pad size corresponds to the first predetermined pitch. Hence, the first predetermined pitch defined for the first spacing rule is 30 mils. For illustration purposes, an anti-pad of the at least one conductive path 312 is exemplarily represented as ‘A’ (as shown in FIG. 3C).

In another scenario, for each conductive path of the pair of conductive paths of the at least one conductive path 312 associated with the set of signals corresponding to the different high-current power/ground signals, the second predetermined pitch defined for the second spacing rule may be 18 mils. The second predetermined pitch between the pair of conductive paths is exemplarily represented as ‘P2’ (as shown in FIG. 3D).The second predetermined pitch of 18 mils is the sum of the DHS (10 mils) of each conductive path and a predefined distance (8 mils) between each conductive path. The predefined distance of 8 mils is defined for the second spacing rule to prevent short between conductive paths in the PCB 310.

In another scenario, for each conductive path of the pair of conductive paths of the at least one conductive path 312 associated with the set of signals corresponding to the same high-current power/ground signals, the third predetermined pitch defined for the third spacing rule may be 16 mils. The third predetermined pitch between the pair of conductive paths is exemplarily represented as ‘P3’ (as shown in FIG. 3D). The third predetermined pitch of 16 mils is the sum of the DHS (10 mils) of each conductive path and a predetermined distance (6 mils) between each conductive path. The predetermined distance of 6 mils is defined for the third spacing rule to configure more conductive paths in the PCB 310. Further, it is low-risk or acceptable for two conductive paths shorting together if the two conductive paths are on the set of signals associated with the second signal property (i.e., the same high-current power/ground signals). In another scenario, the third predetermined pitch may be less than or equal to 10 mils, such that the two conductive paths touch or overlap each other.

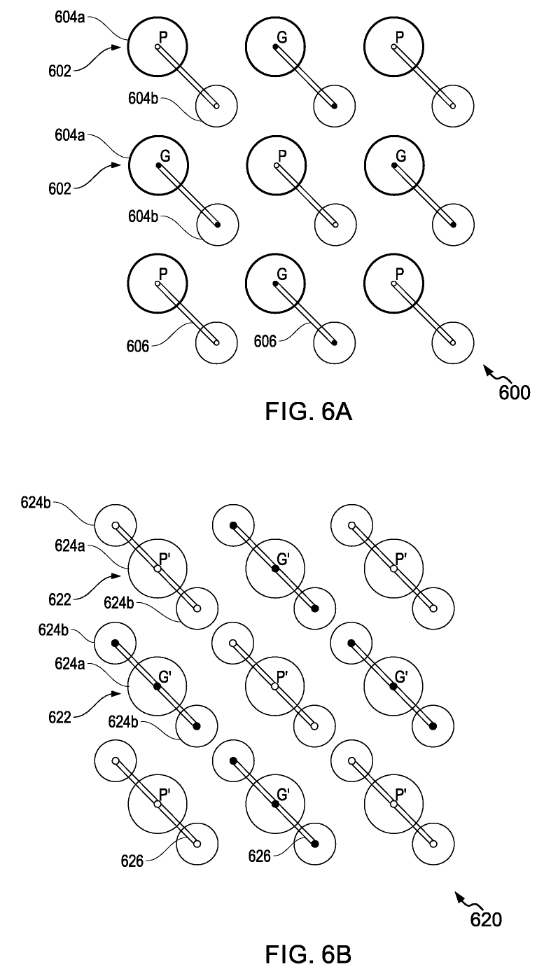

FIG. 6A illustrates an example representation of a PCB 600 depicting a plurality of component pads 602 electrically connected to conductive paths associated with each first terminal and each second terminal through via-in-pad configuration, in accordance with an embodiment of the present disclosure. In this configuration, a set of first terminals (power pins) of the PCB 600 is represented with a reference sign ‘P’, and a set of second terminals (ground pins) of the PCB 600 is represented with a reference sign ‘G’. Herein, ‘P’ indicates the power pins (or the set of first terminals) of the PCB 600, and ‘G’ indicates the ground pins (or the set of second terminals) of the PCB 600. The set of first terminals ‘P’ and the set of second terminals ‘G’ are arranged in a square pattern. Further, the plurality of component pads 602 includes at least one primary component pad 604a and at least one secondary component pad 604b. As explained above, the at least one primary component pad 604a connects at least one primary conductive path (e.g., the at least one primary conductive path 312a) to the corresponding first terminal ‘P’ or the corresponding second terminal ‘G’. Similarly, the at least one secondary component pad 604b connects at least one secondary conductive path (e.g., the at least one secondary conductive path 312b) to the corresponding first terminal ‘P’ or the corresponding second terminal ‘G’. The at least one primary conductive path and the at least one secondary conductive path are not depicted in FIG. 6A. However, it should be noted that the at least one primary conductive path and the at least one secondary conductive path being electrically connected to the at least one primary component pad 604a and the at least one secondary component pad 604b are arranged in square pattern. For example, the at least one primary component pad may be 20 mils, and the at least one secondary component pad 604b may be 14 mils. Further, the number of the primary component pads 604a and the secondary component pads 604b is directly proportional to the number of conductive paths.

In the via-in-pad configuration, the primary component pad 604a is directly placed on each first power terminal ‘P’ and each second ground terminal ‘G’. Thus, the at least one primary component pad 604a overlaps the set of first terminals ‘P’ and the set of second terminals ‘G’. For illustration purposes, the overlapping of the at least one primary component pad 604a on each first terminal ‘P’ and each second terminal ‘G’ is depicted using ‘bold line thickness’. The at least one secondary conductive pad 604b is placed at a distance from the at least one primary component pad 604a. The at least one secondary conductive pad 604b is electrically connected to each first terminal ‘P’ and each second terminal ‘G’ using a conductive feature 606. The conductive feature 606 may be copper traces.

FIG. 6B illustrates an example representation of a PCB 620 depicting a plurality of component pads 622 electrically connected to conductive paths associated with each first terminal and each second terminal through dog-bone fan-out configuration, in accordance with an embodiment of the present disclosure. In this configuration, a set of first terminals of the PCB 620 is represented with a reference sign P’, and a set of second terminals of the PCB 620 is represented with a reference sign G’. Herein, P’ indicates the power pins (or the set of first terminals) of the PCB 600, and G’ indicates the ground pins (or the set of second terminals) of the PCB 620. The set of first terminals P’ and the set of second terminals G’ are arranged in a square pattern. Further, the plurality of component pads 622 includes at least one primary component pad 624a and at least one secondary component pad 624b. For example, the set of first terminals P’ and the set of second terminals G’ may be 20 mils. The at least one primary component pad 624a and the at least one secondary component pad 624b may be 14 mils. Further, the number of the primary component pads 624a and the secondary component pads 624b are directly proportional to the number of conductive paths.

In this configuration, the at least one primary component pad 624a is electrically connected to (or placed on) the corresponding first terminal ‘P’’ and the corresponding second terminal ‘G’’. Further, the at least one secondary component pad 624b is electrically connected to at least one primary conductive path (e.g., the at least one primary conductive path 312a) and at least one secondary conductive path (e.g., the at least one secondary conductive path 312b) associated with each first terminal ‘P’’ and the corresponding second terminal ‘G’’. Hence, the at least one primary conductive path and the at least one secondary conductive path are placed at the distance from the corresponding first terminal P’ and the corresponding second terminal G’. The at least one primary conductive path and the at least one secondary conductive path are not depicted in FIG. 6B. However, it should be noted that the at least one primary conductive path and the at least one secondary conductive path being electrically connected to the at least one secondary component pad 604b are arranged in a square pattern. The at least one secondary conductive pad 624b is placed at a distance from the at least one primary component pad 604a. For example, the at least one primary component pad 624a, and the at least one secondary component pad 624b may be placed at the distance of 19 mils from the center of the corresponding first terminal P’ and the corresponding second terminal G’. Hence, the at least one primary conductive path and the at least one secondary conductive path are placed at the distance of 19 mils from the center of the corresponding first terminal P’ and the corresponding second terminal G’. Further, the at least one secondary conductive pad 624b is electrically connected to the at least one primary conductive pad 624a being connected to the corresponding first terminal ‘P’ and the corresponding second terminal ‘G’ through a conductive feature 626. The conductive feature 626 may be copper traces

Additionally, other design parameters may be optimized for enabling more PTH via (i.e., the at least one conductive path 312) per BGA power/ground pins (i.e., the set of first terminals 320 and the set of second terminals 321). The other design parameters may include a drill size, plating thickness, the plurality of component pads, anti-pad size, inner layer component pad size, and the like. The detailed explanation of the other design parameters is mentioned below.

Drill aspect ratio: A total thickness of the PCB 310 divided by the DHS of each conductive path of the at least one conductive path 312 is known as drill or plating aspect ratio. For example, the total thickness of the PCB 310 is 100 mils and the DHS is 10 mils, thus the drill or plating aspect ratio is 10:1. Further, minimum DHS is generally determined by the drilling and subsequent plating capability of the PCB fabricator. Hence, the smaller the DHS, the more PTH vias (or the conductive paths) may be accommodated in a fixed area of the PCB 310. However, the smaller DHS includes less copper cross-section area which is not recommended for optimum power delivery. Thus, for the same number of conductive paths, it is recommended to have a larger DHS to maximize the copper area.

Plating thickness: The plating thickness refers to the layer of a conductive material (e.g., copper) deposited onto the walls of each conductive path or surface during the PCB manufacturing process. This plating ensures reliable electrical conductivity and structural integrity between layers (such as the power plane 313 and the ground plane 314) of the PCB 310. For example, the plating thickness may be 1 mil for each conductive path. From an electrical performance perspective, it is preferred to have more plating thickness and even fill the conductive material inside each conductive path to reduce the resistance.

The plurality of component pads 311 is usually determined based on connection configuration such as the via-in-pad configuration or the dog-bone fan-out configuration. Some non-limiting examples of the plurality of component pads 311 may include solder pads, external layer conductive path pads, and internal layer conductive path pads. The solder pads may be provided on external layers of the PCB (such as the PCB 310) for soldering other components, such as the IC (see, 301 of FIG. 3A). The external layer conductive path pads are on the top and bottom of the at least one conductive path 312. The external layer conductive path pads are required for plating of the at least one conductive path 312 and mechanical reliability. In the via-in-pad configuration, the component pads include the solder pads and the external layer conductive path pads. The inner layer conductive path pads are used for the at least one conductive path associated with the set of third terminals.

Inner layer anti-pad size: For conventional designs, the power/ground anti-pad size (diameter) is determined as the sum of the DHS and a radial air gap (no copper) registration tolerance. For example, 10 mil radial air gap is added to the 10 mil DHS for a 20 mil component pad, so the anti-pad size is 30 mil. However, for the PCB 310, the extra via(s) to be added are on the same net as the original via so a smaller anti-pad size can be used. For example, 7 mil radial air gap is added the 10 mil DHS, so the anti-pad size is 24 mil. The smaller Power/Ground anti-pad size is critical for having more PTH vias and keeping more copper plane areas, so it is strongly recommended to keep the Power/Ground anti-pad as small as possible within manufacturing capabilities.

In one example scenario, for conductive paths associated with the signal pins connecting to inner layer component pads, an anti-pad size is listed below:
Signal layer: the size of the inner layer component pad on the signal layer is determined by the DHS (D) and the registration tolerance. For example, 10 mils DHS (D) with 4 mils radial registration tolerance (D+4) requires an 18 mils anti-pad size.
Power/Ground layer: Copper is removed on all the power and ground planes to form an anti-pad to prevent the conductive paths of the signal layer from shorting with the power/ground planes. In this scenario, the anti-pad size is dependent on the same DHS and a typical anti-pad registration tolerance on the power/ground layers. For example, 10 mils DHS (D) with 8 mil radial registration tolerance (D+8) requires a 26 mil anti-pad size.

In another example scenario, for conductive paths associated with the power pins connecting to the corresponding power inner layers, an anti-pad size is listed below:
Signal layer: remove all non-functional pads on the signal layers.
Ground layer: D+8 anti-pad size on the power layers.
Power layer: The conductive paths associated with the power pins drilled through the power planes.

In another example scenario, for conductive paths associated with the ground pins connecting to the corresponding ground (GND) layers, an anti-pad size is listed below:
Signal layer: remove all non-functional pads on the power/ground layers.
Ground layer: the conductive paths are drilled through the ground planes.
Power layer: D+8 anti-pad size on the ground layers.

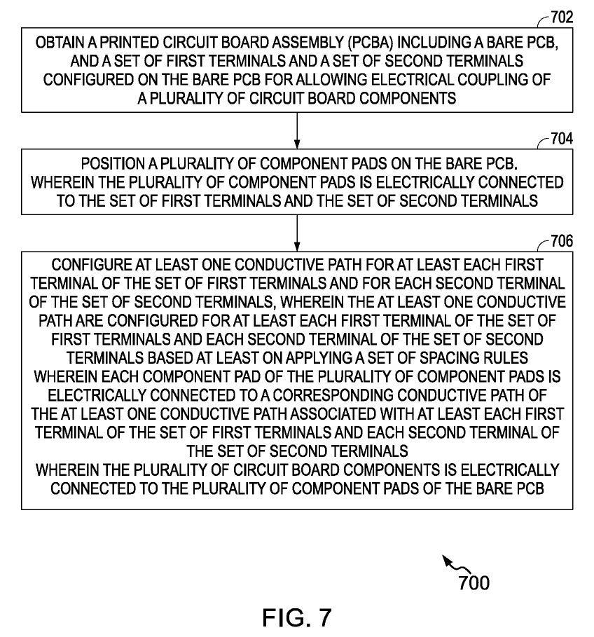

FIG. 7 illustrates a flow diagram of a method 700 for configuring conductive paths in a printed circuit board assembly (PCBA), in accordance with an embodiment of the present disclosure. The method 700 starts at operation 702.

At operation 702, the method 700 includes obtaining a printed circuit board assembly (PCBA) including a bare PCB, and a set of first terminals and a set of second terminals configured on the PCB for allowing electrical coupling of a plurality of circuit board components.

At operation 704, the method 700 includes positioning a plurality of component pads on the bare PCB. The plurality of component pads is electrically connected to the set of first terminals and the set of second terminals.

At operation 706, the method 700 includes configuring at least one conductive path for at least each first terminal of the set of first terminals and for each second terminal of the set of second terminals. The at least one conductive path is configured for at least each first terminal of the set of first terminals and each second terminal of the set of second terminals based at least on applying a set of spacing rules. Further, each component pad of the plurality of component pads is electrically connected to a corresponding conductive path of the at least one conductive path associated with at least each first terminal of the set of first terminals and each second terminal of the set of second terminals. Furthermore, the plurality of circuit board components is electrically connected to the plurality of component pads of the bare PCB. Further, the one or more operations for configuring conductive paths in a printed circuit board (PCB) are already explained with reference to FIGS. 1 to 6A-6B, therefore they are not reiterated herein for the sake of brevity.

The following figures describe various embodiments of SV-PDN vias used together with multiple PCB subassemblies.

### SV-PDN Vias with Multiple PCB Subassemblies

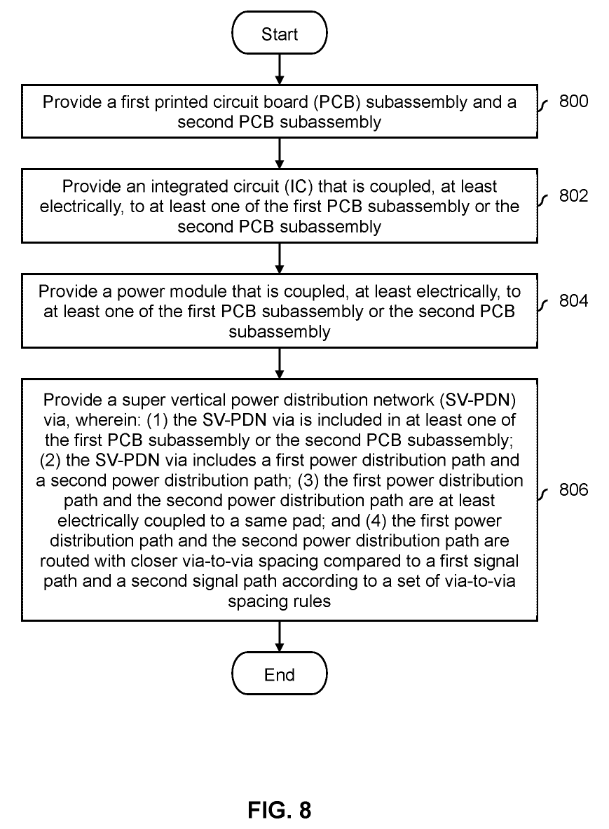

FIG. 8 is a flowchart illustrating an embodiment of a process to assemble a system with SV-PDN vias and multiple PCB subassemblies.

At 800, a first printed circuit board (PCB) subassembly and a second PCB subassembly are provided, at least electrically.

A PCB subassembly is a PCB that is coupled (e.g., electrically and/or physically) to one or more other PCB subassemblies to form, assemble, or otherwise generate a larger system. In some applications, a first PCB subassembly is associated with (e.g., high frequency) signals and a second PCB subassembly is associated with power distribution. To put it another way, most or all of the paths (including vias) routed within the first PCB subassembly are associated with carrying (e.g., data and/or control) signals whereas most or all of the paths (including vias) routed within the second PCB subassembly are associated with distributing or otherwise carrying power (e.g., electrically connected to a power plane or a ground plane).

In some embodiments, at least one of the first PCB subassembly or the second PCB subassembly includes a High-Density Interconnect (HDI) PCB.

At 802, an integrated circuit (IC) that is coupled, at least electrically, to at least one of the first PCB subassembly or the second PCB subassembly is provided.

In FIG. 3B, for example, IC 301 shows an example of an IC having the characteristics and/or properties recited by step 802.

At 804, a power module that is coupled, at least electrically, to at least one of the first PCB subassembly or the second PCB subassembly is provided.

In some embodiments, a power module includes one or more of the following: DC/DC converters, power field effect transistors (powerFET), capacitors, resistors, inductors, power controllers, voltage regulator modules (VRM), and/or a z-axis power delivery (ZPD) module. In the example of FIG. 3B, DC/DC converter 303 shows an example of a power module.

At 806, a super vertical power distribution network (SV-PDN) via is provided, wherein: (1) the SV-PDN via is included in at least one of the first PCB subassembly or the second PCB subassembly; (2) the SV-PDN via includes a first power distribution path and a second power distribution path; (3) the first power distribution path and the second power distribution path are at least electrically coupled to a same pad; and (4) the first power distribution path and the second power distribution path are routed with closer via-to-via spacing compared to a first signal path and a second signal path according to a set of via-to-via spacing rules.

See, for example, FIG. 3B. Conductive path 312a shows an example of a first power distribution path, conductive path 312b shows an example of a second power distribution path, and pads 311a and 311b show examples of a (same) pad to which those power distribution paths are coupled to, at least electrically.

It may be helpful to illustrate some example systems which perform the process of FIG. 8. The following figures describe various embodiments of systems which perform the process of FIG. 8.

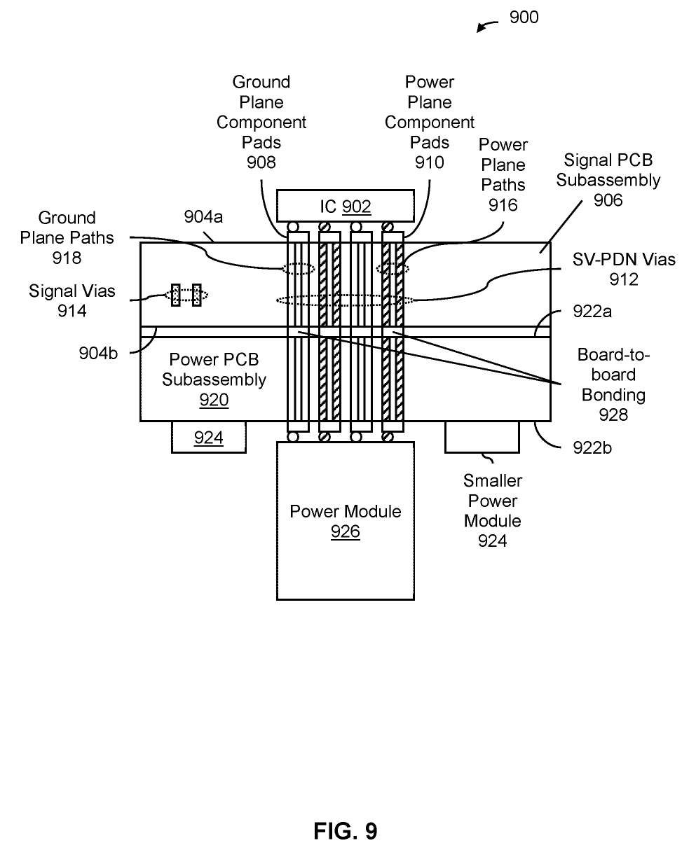

FIG. 9 is a diagram illustrating an embodiment of a system with a power PCB subassembly and a signal PCB subassembly which are connected through board-to-board bonding. The exemplary system 900 shown here shows one embodiment of a system that performs the process of FIG. 8. For example, the system 900 has an IC 902, a first PCB subassembly and a second PCB subassembly (e.g., 906 and 920), a power module 926, and SV-PDN vias 912 having all of the properties and/or characteristics recited in FIG. 8.

In some applications, it may be desirable to have a system (e.g., 900) which has multiple PCB subassemblies that are coupled together instead of a single PCB. For example, signal PCB subassembly 906 may be assembled or otherwise manufactured using different materials, characteristics, dimensions (e.g., path size and/or drill hole size), and/or techniques compared to power PCB subassembly 920. In one such example, the signal PCB subassembly 906 is a High-Density Interconnect (HDI) PCB which is better suited to carrying high-frequency signals. However, HDI PCB is not suitable for power transmission. Instead, power PCB subassembly 920 (at least in this example) is a non-HDI PCB with thicker copper paths which are better for power transmission.

In this example, IC 902 is disposed on an upper surface 904a of a signal PCB subassembly 906. In some embodiments, the IC 902 includes one or more of: a processor, a memory, a system on chip (SoC), an Application Specific Integrated Circuit (ASIC), or an Area Array Package (AAP). The IC 902 and signal PCB subassembly 906 are coupled to each other via component pads, including ground plane component pads 908 and power plane component pads 910.

The signal PCB subassembly 906 includes multiple vias, including SV-PDN vias 912 and signal vias 914. The SV-PDN vias 912 in turn include power plane paths 916 and ground plane paths 918. The former are so named because they are electrically connected to horizontal power planes (not shown) within power PCB subassembly 920 and the latter are so named because they are electrically connected to horizontal ground planes (not shown) within a given PCB subassembly. As described above, SV-PDN vias (e.g., 912) are routed with closer via-to-via spacing (e.g., between a first power distribution path and a second power distribution path) compared to signal vias such as 914 (e.g., between a first signal path and a second signal path) per a set of via-to-via.

A power PCB subassembly 920 is disposed on a lower surface 904b of the signal PCB subassembly 906. In this example system 900, the power PCB subassembly 920 (like the signal PCB subassembly 906) includes SV-PDN vias (e.g., 912). To connect corresponding SV-PDN vias 912 with each other in the two PCB subassemblies 906 and 920, board-to-board bonding 928 is used. For example, board-to-board bonding 928 may include soldering, sintering, hybrid bonding, etc. At this example interface between PCB subassemblies 906 and 920, there is no IC so there are no solder balls or pins (e.g., from an IC) and nor are there component pads to make the board-to-board connection.

Disposed on the lower surface 922b of the power PCB subassembly 920 are multiple power modules, including two smaller power modules 924 and a larger power module 926. In this example, the larger power module 926 is disposed directly beneath (i.e., vertically aligned with) IC 902. To describe this positioning more formally, IC 902 and power module 926 are positioned along a (e.g., vertical) axis that is perpendicular to the largest surfaces 904a and 904b and 922a and 922b of PCB subassemblies 906 and 920. The larger power module 926 supplies power to the IC, via the SV-PDN vias 912 in the signal PCB subassembly 906 and the power PCB subassembly 920. By using SV-PDN vias 912 instead of non-SV-PDNvias through the PCB subassemblies 906 and 920, the SV-PDN vias 912 can be routed or otherwise placed closer to each other compared to signals vias 914 in the signal PCB subassembly 906, reducing power loss over the SV-PDN vias (e.g., because there is more cross sectional area through those vias) and also mitigating the amount of space taken up by the SV-PDN vias (e.g., because those vias can be placed closer to each other).

As is shown in this example, in some embodiments, a first PCB subassembly (e.g., 906) includes a first set of one or more SV-PDN vias (e.g., 912) and a second PCB subassembly (e.g., 920) includes a second set of one or more SV-PDN vias (e.g., 912).

As is shown in this example, in some embodiments, a first PCB subassembly (e.g., recited in step 800 of FIG. 8) includes a signal PCB subassembly (e.g., 906); a second PCB subassembly (e.g., recited in step 800 of FIG. 8) includes a power PCB subassembly (e.g., 920), the power module (e.g., 926) is vertically aligned with the IC (e.g., 902), the IC is disposed on a surface of the signal PCB subassembly, and the power module is disposed on a surface of the power PCB subassembly.

As will be described in more detail below, in some embodiments, assembling the exemplary system 900 includes first laminating or otherwise coupling the signal PCB subassembly 906 and the power PCB subassembly 920 to each other, at lower surface 904b and upper surface 922a, respectively. Then, with the two PCB subassemblies 906 and 920 coupled together, vertical holes are drilled through the signal PCB subassembly 906 and the power PCB subassembly 920 for the SV-PDN vias. For example, this sequence of laminating and then drilling may be preferable because it is a cost-effective way to electrically connect the top board and bottom board. Other methods (e.g., connectors, sintering and soldering, etc.) can make similar electrical connections but have higher costs and/or lower density.

In some embodiments, the IC 902 is a processor. As processors become more powerful, larger power modules (e.g., 926) are required to supply power to the more-powerful processors. In such applications, the power that is lost during transmission over the SV-PDN vias 912 becomes a more important consideration. To that end, the following figure shows an example where a power module is semi-embedded in a power PCB subassembly to reduce power loss during transmission.

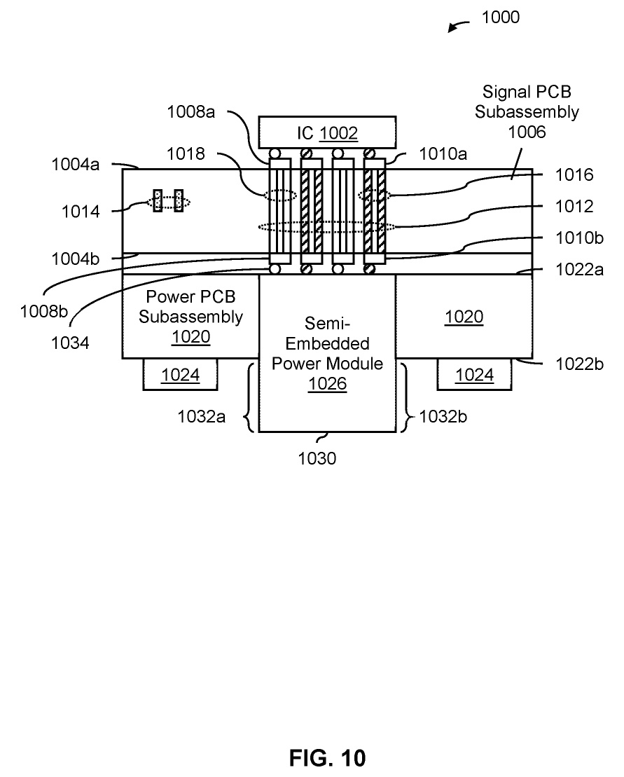

FIG. 10 is a diagram illustrating an embodiment of a system with a power module semi-embedded in a power PCB subassembly. The exemplary system 1000 shown here shows one embodiment of a system that performs the process of FIG. 8. For example, the system 1000 has an IC 1002, a first PCB subassembly and a second PCB subassembly (e.g., 1006 and 1020), a power module 1026, and SV-PDN vias 1012 having all of the properties and/or characteristics recited in FIG. 8. The example configuration shown here may be desirable in applications where shorter SV-PDN vias (e.g., compared to the surface-mounted power module configuration shown in FIG. 9) are desired.

In this example, the IC 1002 is surface mounted on a first surface 1004a of the signal PCB subassembly 1006. The semi-embedded power module 1026 is mounted, attached, or otherwise coupled to the other surface 1004b of the signal PCB subassembly 1006. The IC 1002 is powered by the semi-embedded power module 1026 via SV-PDN vias 1012 which in turn includes power plane paths 1016 and ground plane paths 1018. The SV-PDN vias 1012 have closer via-to-via spacing compared to signal vias, such as 1014. The power-supplying paths between the IC 1002 and semi-embedded power module 1026 also include component pads, such as power plane component pads 1010a and 1010b and ground plane component pads 1008a and 1008b.

In this example, there are additional, smaller power modules 1024 that are surface mounted to the bottom surface 1022b of the power PCB subassembly 1020 which supply (e.g., additional) power to the system.

In this example, the power module 1026 is semi-embedded within the power PCB subassembly 1020. For example, a cavity may be drilled or cut out of the power PCB subassembly 1020, sized to fit the power module 1026. The power module 1026 is then placed into the cavity with the solder balls or pins (e.g., 1034) disposed towards the bottom surface 1004b of the signal PCB subassembly 1006. In some embodiments, an adhesive is used to couple or otherwise attach the power module 1026 and power PCB subassembly 1020 to each other, and/or fill in any gaps between the two. Similarly, the bottom surface 1004b of signal PCB subassembly 1006 and the upper surface 1022a of power PCB subassembly 1020 may be coupled to each other using any appropriate material and/or technique.

The power module 1026 is semi-embedded, in the sense that it remains partially exposed, even after insertion into the power PCB subassembly 1020. For example, the side (i.e., 1030) that is opposite the side with the solder balls or pins 1034 remains exposed. Similarly, at least some of the side surfaces (e.g., 1032a and 1032b) of the power module 1026 remain exposed.

As shown in this example, in some embodiments, the first PCB subassembly includes a signal PCB subassembly (e.g., 1006), the second PCB subassembly includes a power PCB subassembly (e.g., 1020), the power module is vertically aligned with the IC (see, e.g., the vertical alignment of IC 1002 and semi-embedded power module 1026), the IC is disposed on a surface of the signal PCB subassembly, and the power module is semi-embedded within the power PCB subassembly (see, e.g., how the power module 1026 is semi-embedded in power PCB subassembly 1020).

Systems with PCB subassemblies have a variety of configurations. The following figure shows one example where a power module is completely and/or fully embedded in a power PCB subassembly.

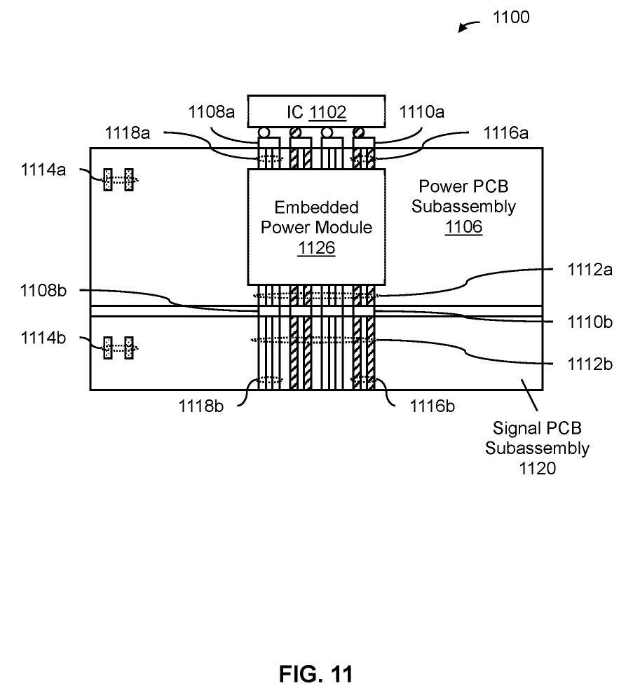

FIG. 11 is a diagram illustrating an embodiment of a system with a power module semi-embedded in a power PCB subassembly. The exemplary system 1100 shown here shows one embodiment of a system that performs the process of FIG. 8. For example, the system 1100 has an IC 1102, a first PCB subassembly and a second PCB subassembly (e.g., 1106 and 1120), a power module 1126, and SV-PDN vias 1112a and 1112b having all of the properties and/or characteristics recited in FIG. 8. For example, with respect to step 806 of FIG. 8, power plane paths 1116a and 1116b and ground plane paths 1118a and 1118b show examples of a first and a second power distribution path; and pads 1108a, 1108b, 1110a, and 1110b show an example of a same pad to which the power distribution paths are at least electrically connected; where signal vias 1114a and 1114b are routed with larger via-to-via spacing (compared to the power distribution paths) according to a set of via-to-via spacing rules.

In this example, the power module 1126 is (e.g., completely and/or fully) embedded in the power PCB subassembly 1106. For example, all sides of the power module 1126 are fully surrounded or enveloped by the power PCB subassembly with no exposed surfaces of the power module 1126.

As is shown in this example, in some embodiments, a first PCB subassembly includes a signal PCB subassembly (e.g., 1120), a second PCB subassembly includes a power PCB subassembly (e.g., 1106), the power module (e.g., 1126) is vertically aligned with an IC (e.g., 1102), the IC is disposed on a surface of the signal PCB subassembly; and the power module is embedded within the power PCB subassembly.

In the examples of FIGS. 9 – 11, the number of PCB subassemblies is merely exemplary and is not intended to be limiting. The following figures show some examples with three PCB subassemblies.

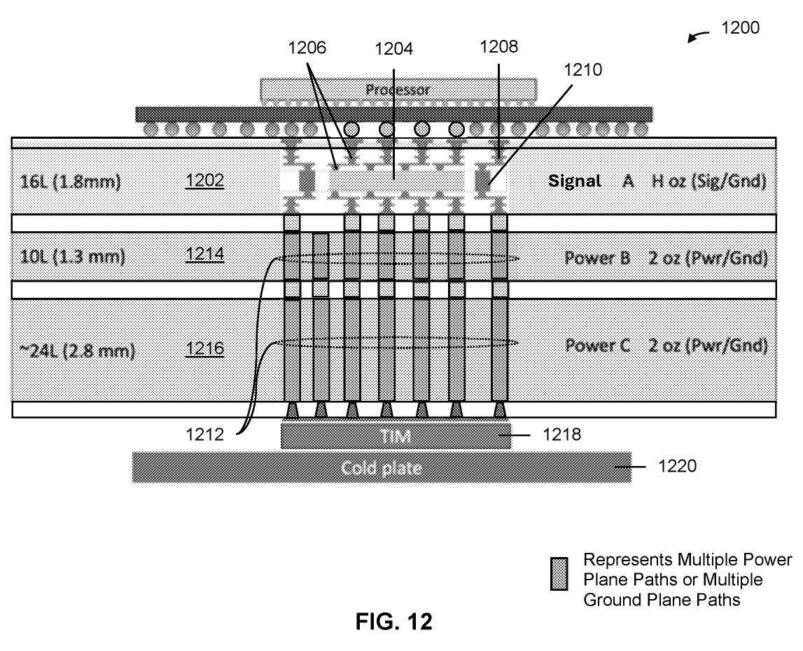

FIG. 12 is a diagram illustrating an embodiment of a system with three PCB subassemblies, where a power module is fully embedded in a top PCB subassembly associated with high-speed signal transmission. The exemplary system 1200 shown here shows one embodiment of a system that performs the process of FIG. 8.

In this example system 1200, signal A PCB subassembly 1202 is used to transmit (e.g., high-speed) signals and is an HDI PCB. The signal and ground paths in PCB subassembly 1202 use a half ounce (Hoz) of copper per square foot which corresponds to a thickness of within a range of 15.2μm – 16μm. Signal A PCB subassembly 1202 has 16 routing layers (L), corresponding to a height of 1.8mm.

Signal A PCB subassembly 1202 includes embedded components, including (fully) embedded power module 1204. Due to limits on the number of (e.g., consecutive) vertically-stacked micro vias in the HDI PCB subassemblies (e.g., 1202), embedded power module 1204 is connected to the top surface and bottom surface of signal A PCB subassembly 1202 using offset vias 1206 in order to comply with the limits on the number of vertically stacked micro vias. In this example, 1206 is an offset micro via but in some other embodiments 1206 is a stacked micro via.

In this example, power is routed vertically through the signal A PCB subassembly 1202 (e.g., in regions not blocked by the embedded power module 1204) using a combination of stacked micro vias 1208 (which use HDI technology) as well as thicker plugs 1210 which use standard and/or non-HDI technology. It is noted that these stacked micro vias 1208 and plugs 1210 are connected to and/or at least partially vertically aligned with some of the SV-PDN vias 1212 in the other PCB subassemblies 1214 and 1216.

Power B PCB subassembly 1214 is located in the middle of the three layered PCB subassemblies. The power and ground paths in PCB subassembly 1214 use 2 ounces (2oz) of copper per square foot which corresponds to a thickness of ~70μm. Power B PCB subassembly 1214 has 10 routing layers (L) and has a height of 1.3mm.

Power C PCB subassembly 1216 is located at the bottom of the three layered PCB subassemblies. The power and ground paths in PCB subassembly 1216 use 2 ounces (2oz) of copper per square foot. Power C PCB subassembly 1216 has approximately 24 routing layers (L) and has a height of 2.8mm.

Power B PCB subassembly 1214 and power C PCB subassembly 1216 both include SV-PDN vias 1212 to route or otherwise transport power plane paths and ground plane paths vertically. For brevity and readability, in FIG. 12 and later figures, each vertical SV-PDN via 1212 corresponds to and/or represents multiple ground plane paths or multiple power plane paths.

Below power C PCB subassembly 1216 are a thermal interface material (TIM) 1218 and cold plate 1220. TIM 1218 pulls heat out of the PCB subassemblies and moves the heat to cold plate 1220 which dissipates the heat. For example, with more PCB subassemblies (e.g., three or more), heat dissipation becomes more of a concern.

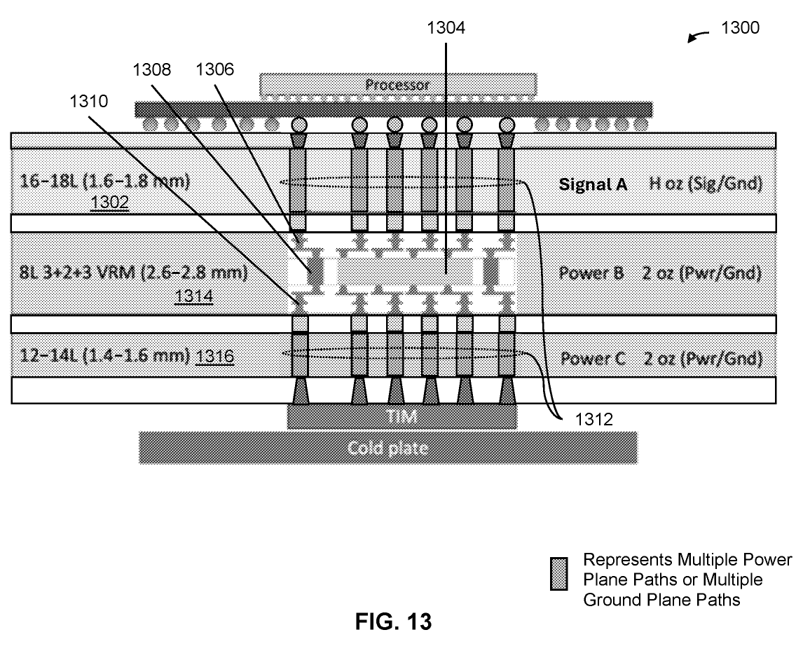

FIG. 13 is a diagram illustrating an embodiment of a system with three PCB subassemblies, where a power module is fully embedded in a middle PCB subassembly associated with power transmission. The exemplary system 1300 shown here shows one embodiment of a system that performs the process of FIG. 8.

In this example, the top PCB subassembly is (e.g., high speed) signal A PCB subassembly 1302 and is an HDI PCB subassembly. It has 16 – 18 layers, which corresponds to a thickness of 1.6mm – 1.8mm. The middle PCB subassembly is power B PCB subassembly 1314. It has eight layers total (e.g., three layers 1306 above power module 1304, two layers that are level with power module 1304 and plug 1308, and three layers 1310 below power module 1304). This corresponds to a thickness of 2.6mm – 2.8mm. The bottom PCB subassembly is power C PCB subassembly 1316 which has 12 – 14 layers, which corresponds to a thickness of 1.4mm – 1.6mm.

In this example, power module 1304 is (fully) embedded in power B PCB subassembly 1314. Signal A PCB subassembly 1302 and power C PCB subassembly 1316 both include SV-PDN vias 1312 to route or otherwise transport power plane paths and ground plane paths vertically.

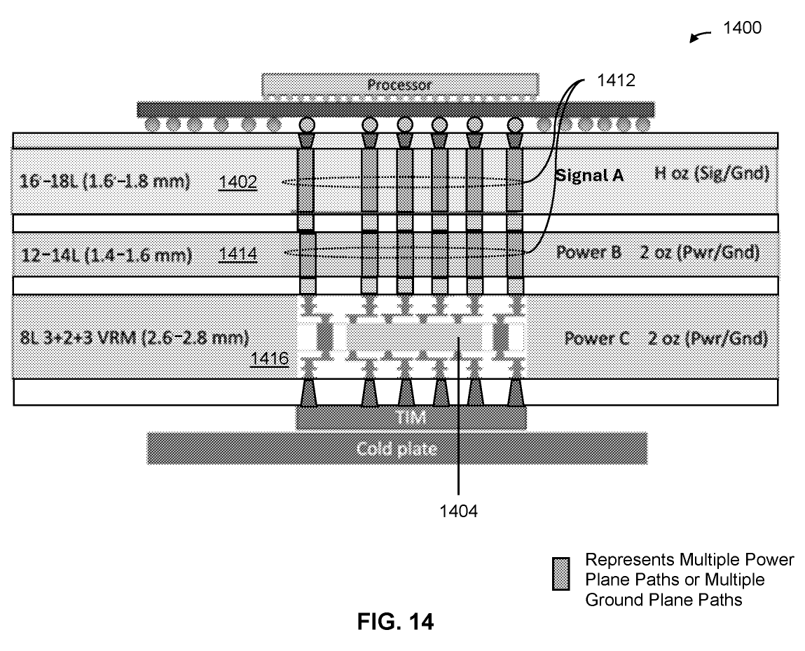

FIG. 14 is a diagram illustrating an embodiment of a system with three PCB subassemblies, where a power module is fully embedded in a bottom PCB subassembly associated with power transmission. The exemplary system 1400 shown here shows one embodiment of a system that performs the process of FIG. 8.

In this example, the top PCB subassembly is (e.g., high speed) signal A PCB subassembly 1402 and is an HDI PCB subassembly. It has 16 – 18 layers, which corresponds to a thickness of 1.6mm – 1.8mm. The middle PCB subassembly is power B PCB subassembly 1414. It has 12 – 14 layers, which corresponds to a thickness of 1.4mm – 1.6mm. The bottom PCB subassembly is power C PCB subassembly 1416 which has eight layers, corresponding to a thickness of 2.6mm – 2.8mm..

In this example, power module 1404 is (fully) embedded in power C PCB subassembly 1416. Signal A PCB subassembly 1402 and power B PCB subassembly 1414 both include SV-PDN vias 1412 to route or otherwise transport power plane paths and ground plane paths vertically.

In some embodiments, a system includes multiple, vertically-stacked power modules. The following figures show some examples of this.

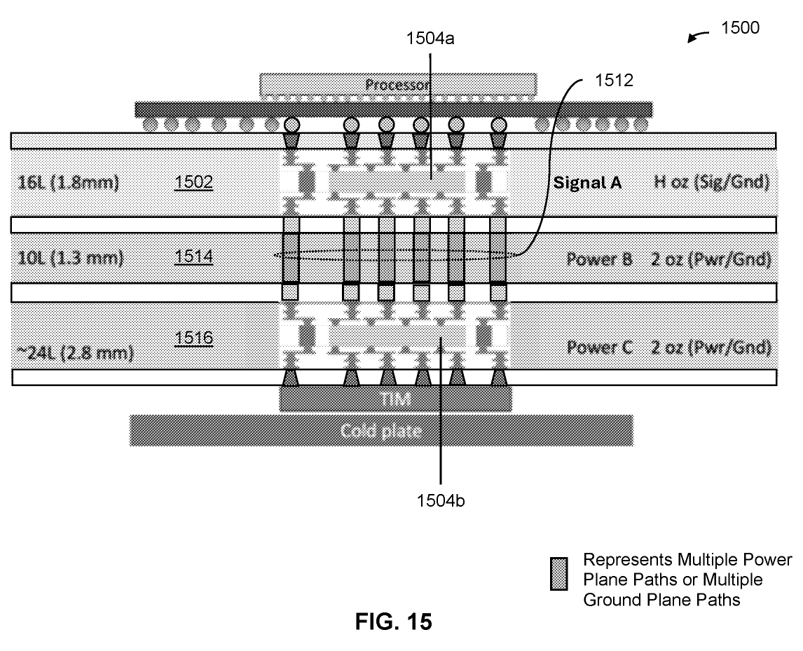

FIG. 15 is a diagram illustrating an embodiment of a system with three PCB subassemblies, where a first power module is fully embedded in a top PCB subassembly associated with high-speed signal transmission and a second power module is fully embedded in a bottom PCB subassembly associated with power transmission. The exemplary system 1500 shown here shows one embodiment of a system that performs the process of FIG. 8.

In this example, signal A PCB subassembly 1502 (at top) includes a first fully-embedded power module 1504a. Power C PCB subassembly 1516 (at bottom) includes a second fully-embedded power module 1504b. SV-PDN vias 1512 in power B PCB subassembly 1514 connect the two power modules 1504a and 1504b.

In this example, signal A PCB subassembly 1502 is an HDI PCB subassembly and has 16 layers which corresponds to a thickness of 1.8mm. Power B PCB subassembly 1514 has 10 layers which corresponds to a thickness of 1.3mm. Power C PCB subassembly 1516 has ~24 layers which corresponds to a thickness of 2.8mm.

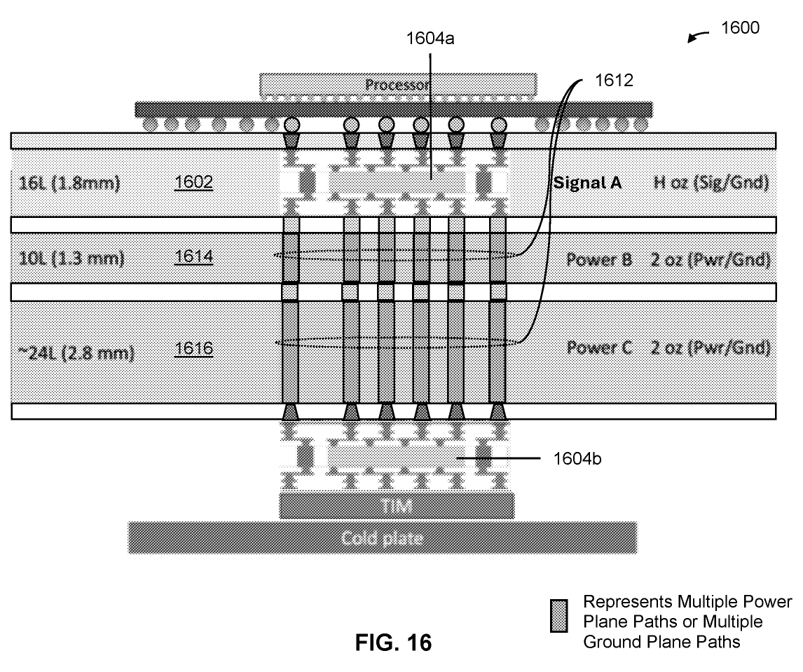

FIG. 16 is a diagram illustrating an embodiment of a system with three PCB subassemblies, where a first power module is fully embedded in a top PCB subassembly associated with high-speed signal transmission and a second power module is surface mounted to a bottom PCB subassembly associated with power transmission. The exemplary system 1600 shown here shows one embodiment of a system that performs the process of FIG. 8.

In this example, signal A PCB subassembly 1602 (at top) includes a first fully-embedded power module 1604a. A second power module 1604b is surface mounted to power C PCB subassembly 1616 (at bottom). Power B PCB subassembly 1614 and power C PCB subassembly 1616 include SV-PDN vias 1612.

In this example, signal A PCB subassembly 1602 is an HDI PCB subassembly and has 16 layers which corresponds to a thickness of 1.8mm. Power B PCB subassembly 1614 has 10 layers which corresponds to a thickness of 1.3mm. Power C PCB subassembly 1616 has ~24 layers which corresponds to a thickness of 2.8mm.

In various embodiments, a PCB subassembly with a (fully) embedded power module may be manufactured in a variety of ways. The following figures show two examples.

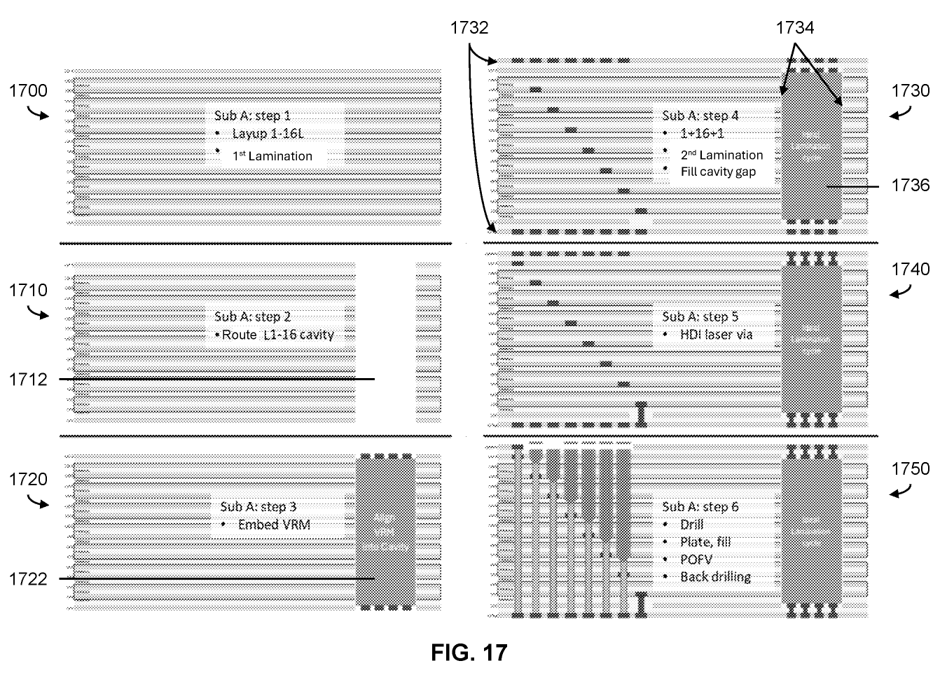

FIG. 17 is a diagram illustrating an embodiment of a sequence of steps to manufacture a PCB subassembly with an embedded power module using multiple laminations. In this example, the PCB subassembly being assembled is an HDI PCB.

At first step 1700, 16 layers are layered up and a first lamination is performed.

At second step 1710, cavity 1712 is routed and/or drilled into the 16 layers.

At third step 1720, a VRM (or, more generally, power module) 1722 is embedded or otherwise inserted into the cavity 1712 drilled during the previous step (1710).

At fourth step 1730, a top layer and bottom layer 1732 are laid on top of and on the bottom of the (e.g., original) 16 layers. A second lamination is performed and the cavity gap 1734 around the VRM 1736 is filled.

At fifth step 1740, HDI-type vias are manufactured, including by laser drilling holes for vias.

At sixth step 1750, drilling and/or via manufacturing using other technologies (i.e., non-HDI technologies) is/are used to manufacture the remaining vias, including drilling, plate and fill (or, more formally, Plated Over Filled Via (POFV)), and/or back drilling.

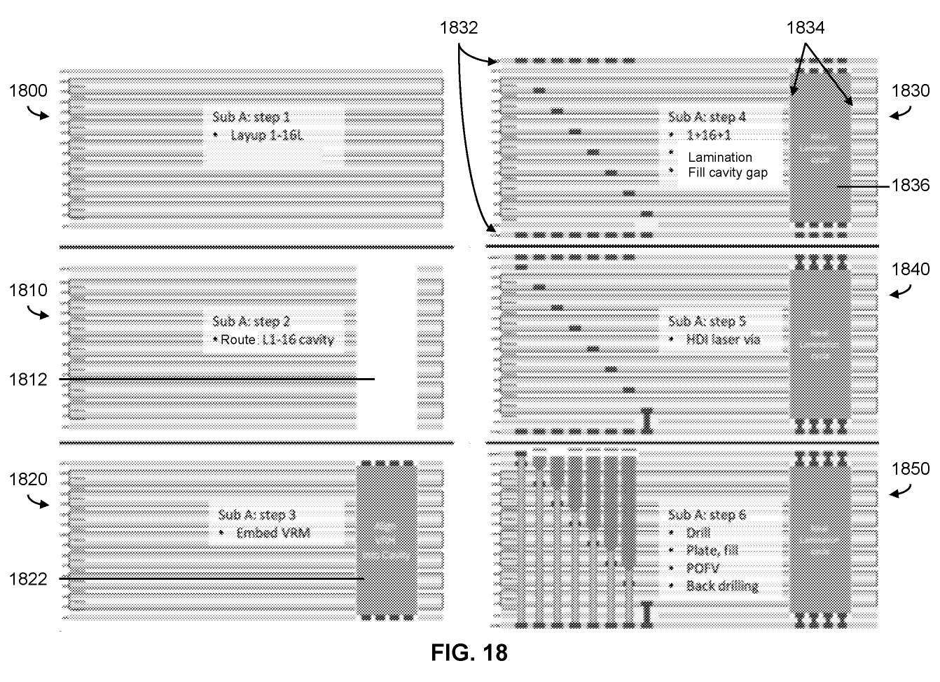

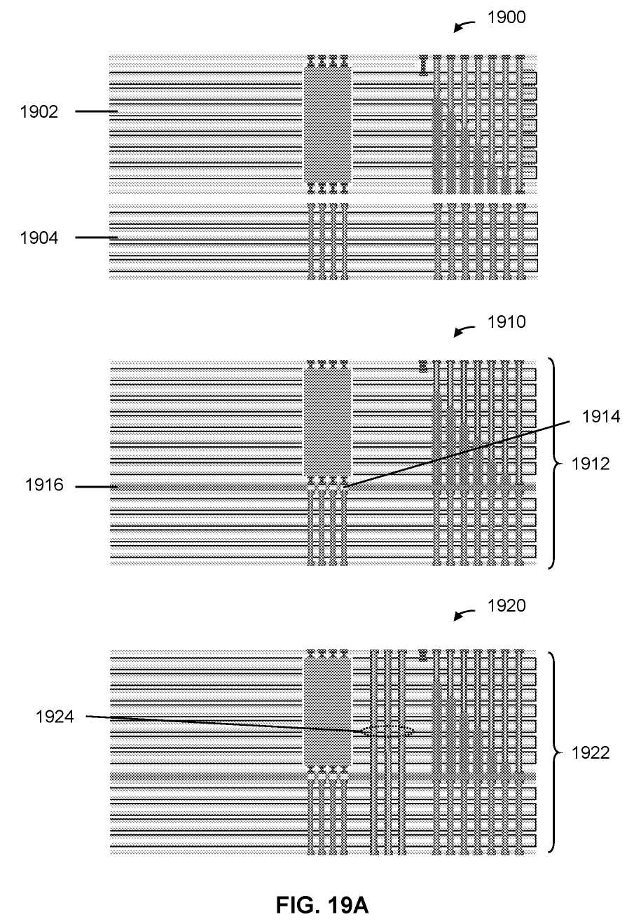

In some embodiments, a single lamination assembly technique is used. For example, in more advanced AI base boards, both critical high speed and high power circuits are integrated into the PCB and may therefore use via structures that requires multiple lamination cycles for the final assembly. For such applications, it may be desirable and/or preferable to use multiple laminations (e.g., per the example of FIG. 17). However, in other applications, it may be desirable and/or preferable to use a single lamination process (e.g., per the example of FIG. 18). For example, many server boards have relatively high product volume and are therefore more cost sensitive. Such applications may prefer a via structure requiring a single lamination cycle for cost reasons.

FIG. 18 is a diagram illustrating an embodiment of a sequence of steps to manufacture a PCB subassembly with an embedded power module using a single lamination.

At first step 1800, 16 layers are layered up.

At second step 1810, cavity 1812 is routed and/or drilled into the 16 layers.

At third step 1820, a VRM (or, more generally, power module) 1822 is embedded or otherwise inserted into the cavity 1812 drilled during the previous step (1810).

At fourth step 1830, a top layer and bottom layer 1832 are laid on top of and on the bottom of the (e.g., original) 16 layers. The (single) lamination process is performed and the cavity gap 1834 around the VRM 1836 is filled.

At fifth step 1840, HDI-type vias are manufactured, including by laser drilling holes for vias.

At sixth step 1850, drilling and/or via manufacturing using other technologies (i.e., non-HDI technologies) is/are used to manufacture the remaining vias, including drilling, plate and fill (or, more formally, Plated Over Filled Via (POFV)), and/or back drilling.

In various embodiments, multiple PCB subassemblies are connected or otherwise attached to each other in a variety of ways. The following figures show some examples.

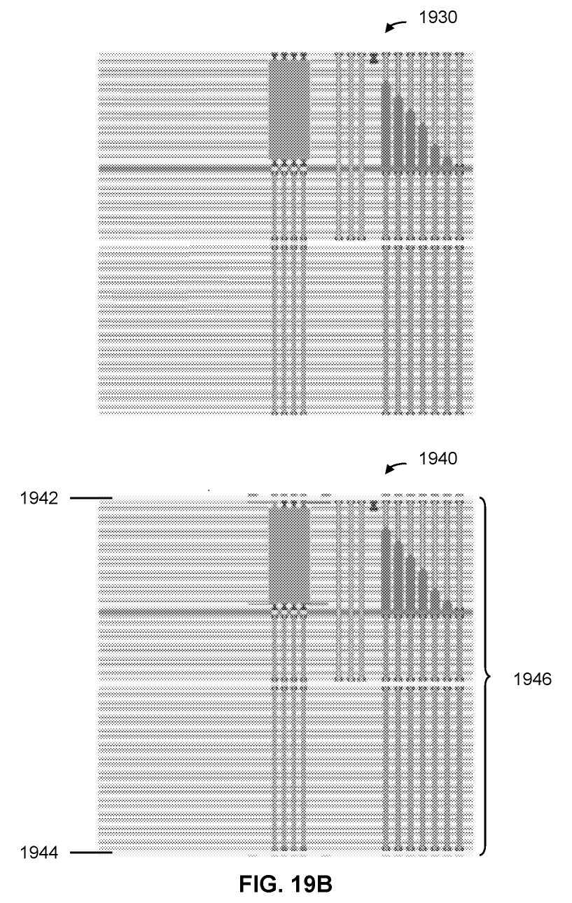

FIG. 19A is a diagram illustrating an embodiment of steps 1 – 3 of a first process to connect multiple PCB subassemblies using sintering paste.

At first step 1900, a 16-layer high-speed signal A PCB subassembly 1902 is embedded with a VRM (or, more generally, power module). Signal A PCB subassembly 1902 further has HDI connections manufactured, an additional top and bottom layer added to the (e.g., starting) 16 layers. Other and/or additional drilling and/or technologies are performed on the signal A PCB subassembly 1902 (e.g., back drilling, plating, etc.) to add additional vias (e.g., POFV). At this first step 1900, the signal A PCB subassembly 1902 is not yet connected to the power B PCB subassembly 1904.

At second step 1910, signal A PCB subassembly and power B PCB subassembly are bonded into a connected A+B subassembly 1912. “ In this example, bonding of the conductive pads is performed using sintering paste 1914 on or at the VRM pads and using prepreg or a dielectric coating 1916 elsewhere to adhere the sub-assemblies.

At third step 1920, connected A+B subassembly 1922 is drilled, plated, and resin filled and CAP plated to generate POFV 1924 in both subassemblies of the connected A+B subassemblies 1922.

FIG. 19B is a diagram illustrating an embodiment of steps 4 and 5 to connect multiple PCB subassemblies using sintering paste and extra HDI layers. FIG. 19B continues the example of FIG. 19A.

At fourth step 1930, after sub-assemblies A and B are bonded together in step 3, the joined A+B sub-assembly is bonded to sub-assembly C using the same sinter paste to the conductive pads and using the prepreg to adhere the sub-assemblies together.

At fifth step 1940, HDI layer 11942 and HDI layer 521944 are laminated at the top and bottom of the connected A+B+C subassemblies 1946. HDI vias are connected to VRM pads. Additional vias (e.g., PFV, PTH, etc.) are added by drilling and plating layers 1 – 52. HDI layers 1 and 2 (including 1942) and HDI layers 51 and 52 (including 1944) are connected by HDI vias.

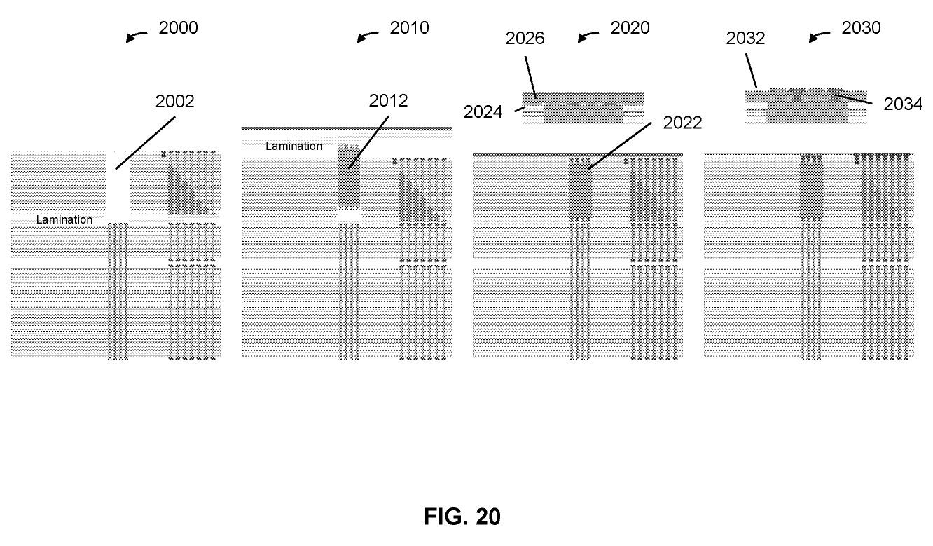

FIG. 20 is a diagram illustrating an embodiment of a second process for connecting multiple PCB subassemblies.

At first step 2000, a recess cavity 2002 is created first. In this example, soldering masks are applied before a lamination cycle.

At second step 2010, VRM 2012 (or, more generally, a power module) is inserted or otherwise assembled into the recess cavity. This occurs before lamination.

At third step 2020, a top layer 2-26 is added for HDI and the gap around VRM 2022 is filled. See, for example, closeup 2024 showing the top of the VRM 2022 with the added top layer 2026 and filled gap.

At fourth step 2030, HDI connections to the pads are created. See, for example, closeup 2032 showing newly-added HDI connections 2034.

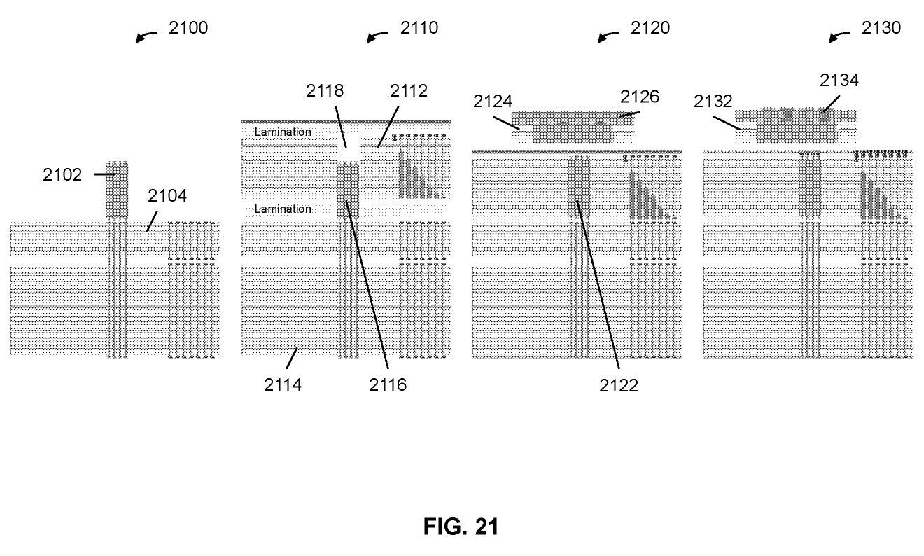

FIG. 21 is a diagram illustrating an embodiment of a third process for connecting multiple PCB subassemblies.

At first step 2100, VRM 2102 (or, more generally, a power module) is soldered to bottom PCB subassembly 2104. In some embodiments, bottom PCB subassembly 2104 includes multiple, connected PCB subassemblies.

At second step 2110, top PCB subassembly 2112 is bonded to a bottom PCB subassembly 2114. Top PCB subassembly 2112 includes a recess cavity 2118 which VRM 2116 fits into.

At third step 2120, a top layer 2126 is added for HDI and the gap around VRM 2122 is filled. See, for example, closeup 2124 showing the top of the VRM 2122 with the added top layer 2126 and filled gap.

At fourth step 2130, HDI connects to the pads. See, for example, closeup 2132 showing newly-added HDI connections 2134.

Although the foregoing embodiments have been described in some detail for purposes of clarity of understanding, the invention is not limited to the details provided. There are many alternative ways of implementing the invention. The disclosed embodiments are illustrative and not restrictive.

1. A system, comprising:
a first printed circuit board (PCB) subassembly;
a second PCB subassembly;
an integrated circuit (IC) that is coupled, at least electrically, to at least one of the first PCB subassembly or the second PCB subassembly;
a power module that is coupled, at least electrically, to at least one of the first PCB subassembly or the second PCB subassembly; and
a super vertical power distribution network (SV-PDN) via, wherein:
the SV-PDN via is included in at least one of the first PCB subassembly or the second PCB subassembly;
the SV-PDN via includes a first power distribution path and a second power distribution path;
the first power distribution path and the second power distribution path are at least electrically coupled to a same pad; and
the first power distribution path and the second power distribution path are routed with closer via-to-via spacing compared to a first signal path and a second signal path according to a set of via-to-via spacing rules.

2. The system of claim 1, wherein:
the first PCB subassembly includes a first set of one or more SV-PDN vias; and
the second PCB subassembly includes a second set of one or more SV-PDN vias.

3. The system of claim 1, wherein:
the first PCB subassembly includes a signal PCB subassembly;
the second PCB subassembly includes a power PCB subassembly;
the power module is vertically aligned with the IC;
the IC is disposed on a surface of the signal PCB subassembly; and
the power module is disposed on a surface of the power PCB subassembly.

4. The system of claim 1, wherein:
the first PCB subassembly includes a signal PCB subassembly;
the second PCB subassembly includes a power PCB subassembly;
the power module is vertically aligned with the IC;
the IC is disposed on a surface of the signal PCB subassembly; and
the power module is semi-embedded within the power PCB subassembly.

5. The system of claim 1, wherein:
the first PCB subassembly includes a signal PCB subassembly;
the second PCB subassembly includes a power PCB subassembly;
the power module is vertically aligned with the IC;
the IC is disposed on a surface of the signal PCB subassembly; and
the power module is embedded within the power PCB subassembly.

6. The system of claim 1, wherein at least one of the first PCB subassembly or the second PCB subassembly includes a High-Density Interconnect (HDI) PCB.

7. The system of claim 1, wherein at least one of the first PCB subassembly or the second PCB subassembly is manufactured using a single lamination process.

8. A method, comprising:
providing a first printed circuit board (PCB) subassembly;
providing a second PCB subassembly;
providing an integrated circuit (IC) that is coupled, at least electrically, to at least one of the first PCB subassembly or the second PCB subassembly;
providing a power module that is coupled, at least electrically, to at least one of the first PCB subassembly or the second PCB subassembly; and
providing a super vertical power distribution network (SV-PDN) via, wherein:
the SV-PDN via is included in at least one of the first PCB subassembly or the second PCB subassembly;
the SV-PDN via includes a first power distribution path and a second power distribution path;
the first power distribution path and the second power distribution path are at least electrically coupled to a same pad; and
the first power distribution path and the second power distribution path are routed with closer via-to-via spacing compared to a first signal path and a second signal path according to a set of via-to-via spacing rules.

9. The method of claim 8, wherein:
the first PCB subassembly includes a first set of one or more SV-PDN vias; and
the second PCB subassembly includes a second set of one or more SV-PDN vias.

10. The method of claim 8, wherein:
the first PCB subassembly includes a signal PCB subassembly;
the second PCB subassembly includes a power PCB subassembly;
the power module is vertically aligned with the IC;
the IC is disposed on a surface of the signal PCB subassembly; and
the power module is disposed on a surface of the power PCB subassembly.

11. The method of claim 8, wherein:
the first PCB subassembly includes a signal PCB subassembly;
the second PCB subassembly includes a power PCB subassembly;
the power module is vertically aligned with the IC;
the IC is disposed on a surface of the signal PCB subassembly; and
the power module is semi-embedded within the power PCB subassembly.

12. The method of claim 8, wherein:
the first PCB subassembly includes a signal PCB subassembly;
the second PCB subassembly includes a power PCB subassembly;
the power module is vertically aligned with the IC;
the IC is disposed on a surface of the signal PCB subassembly; and
the power module is embedded within the power PCB subassembly.

13. The method of claim 8, wherein at least one of the first PCB subassembly or the second PCB subassembly includes a High-Density Interconnect (HDI) PCB.

14. The method of claim 8, wherein at least one of the first PCB subassembly or the second PCB subassembly is manufactured using a single lamination process.
